(19) United States
(12) Patent Application Publication
(10) Pub. No.: US 2025/0047568 A1
(43) Pub. Date: Feb. 6, 2025

(54) TRANSMISSION DEVICE, RECEPTION DEVICE, TRANSMISSION METHOD, AND RECEPTION METHOD

(71) Applicant: SONY GROUP CORPORATION, TOKYO (JP)

(72) Inventors: HIROKI MATSUDA, TOKYO (JP); SHINICHIRO TSUDA, TOKYO (JP); KAZUYUKI SHIMEZAWA, TOKYO (JP)

(21) Appl. No.: 18/717,164

(22) PCT Filed: Dec. 7, 2022
(86) PCT No.: PCT/JP2022/045013

§ 371 Date: Jun. 6, 2024

(30) Foreign Application Priority Data
Dec. 14, 2021 (JP) 2021-202847

(51) Int. Cl. H04L 41/16; H04W 72/11

(52) U.S. Cl. CPC H04L 41/16; H04W 72/11

(57) ABSTRACT

Provided are a transmission device, a reception device, a transmission method, and a reception method capable of improving accuracy of an encoder configured by an AI/ML model on a transmission side.

A terminal device includes an encoder configured by an AI/ML model, encodes RAW data by the encoder, acquires encoded data, and transmits the encoded data and the RAW data to a base station. The base station includes a decoder configured by an AI/ML model, receives encoded data and RAW data from the terminal device, decodes the encoded data by the decoder to acquire decoded data, and verifies whether or not the encoded data is correctly encoded on the basis of a comparison between the RAW data and the decoded data.

### TECHNICAL FIELD

The present disclosure relates to a transmission device, a reception device, a transmission method, and a reception method.

### BACKGROUND ART

At present, as a next-generation mobile communication system, Beyond 5G and 6G have been studied in the 3rd Generation Partnership Project.

In the radio access schemes of Beyond 5G and 6G, further improvement of high speed and high capacity (eMBB: Enhanced Mobile Broadband), multiple simultaneous connections (mMTC: Massive Machine Type Communications), and high reliability and low latency (URLLC: Ultra Reliable and Low Latency Communications) is expected. In order to realize these, processing data transmitted and received by wireless communication using an artificial intelligence/machine learning (AI/ML) model has been studied. For example, Patent Documents 1 and 2 have studied a technique for improving spectrum use efficiency by encoding channel status information (CSI) transmitted from a terminal device to a base station using an AI/ML model to compress the amount of data.

### CITATION LIST

### Non-Patent Document

Non-Patent Document 1: RWS-210170, “Study on AI/ML based air interface enhancement in Rel-18”, VIVO, 3GPP TSG RAN Rel-18 workshop, Electronic Meeting, Jun. 28-Jul. 2, 2021
Non-Patent Document 2: RWS-210373, “AI/ML enabled RAN and NR Air Interface”, Intel Corporation, 3GPP TSG RAN Rel-18 workshop, Electronic Meeting, Jun. 28-Jul. 2, 2021

### SUMMARY OF THE INVENTION

### Problems to be Solved by the Invention

A wireless communication system including a transmission side having an encoder based on an AI/ML model and a reception side having a decoder based on an AI/ML model is considered. At this time, if the training of the encoder on the transmission side is insufficient due to, for example, an insufficient number of training data, there is a possibility that the correctly encoded data is not transmitted to the reception side (the correctly encoded data cannot be received on the reception side). In this case, the decoder on the reception side cannot correctly restore the original data.

The present disclosure is intended to solve the above problems, and an object thereof is to provide a transmission device, a reception device, a transmission method, and a reception method capable of improving the accuracy of an encoder configured by an AI/ML model on a transmission side.

### Solutions to Problems

A transmission device according to the present disclosure includes: an encoder configured by an AI/ML model, and configured to encode a first bit sequence or symbol sequence to acquire a second bit sequence or symbol sequence; and a transmission unit that transmits the first bit sequence or symbol sequence and the second bit sequence or symbol sequence.

Furthermore, a reception device according to the present disclosure includes: a reception unit that receives a first bit sequence or symbol sequence and a second bit sequence or symbol sequence acquired by encoding the first bit sequence or symbol sequence; a decoder configured by an AI/ML model, and configured to decode the second bit sequence or symbol sequence to acquire a decoded bit sequence or symbol sequence; and a control unit that verifies the second bit sequence or symbol sequence on the basis of a comparison between the first bit sequence or symbol sequence and the decoded bit sequence or symbol sequence.

Furthermore, a transmission method according to the present disclosure includes the steps of:

encoding a first bit sequence or symbol sequence by an encoder configured by an AI/ML model, to acquire a second bit sequence or symbol sequence; and

transmitting the second bit sequence or symbol sequence and the first bit sequence or symbol sequence.

Further, a reception method according to the present disclosure includes the steps of: receiving a first bit sequence or symbol sequence and a second bit sequence or symbol sequence acquired by encoding the first bit sequence or symbol sequence;

decoding the second bit sequence or symbol sequence by a decoder configured by an AI/ML model, to acquire a decoded bit sequence or symbol sequence;

and verifying the second bit sequence or symbol sequence on the basis of a comparison of the first bit sequence or symbol sequence and the decoded bit sequence or symbol sequence.

### BRIEF DESCRIPTION OF DRAWINGS

FIG. 1 is a diagram illustrating a configuration of a wireless communication system according to a first embodiment of the present disclosure.

FIG. 2 is a diagram illustrating a configuration of a management device.

FIG. 3 is a diagram illustrating a configuration of a base station.

FIG. 4 is a diagram illustrating a configuration of a relay station.

FIG. 5 is a diagram illustrating a configuration of a terminal device.

FIG. 6 is a block diagram illustrating a detailed configuration of a terminal device and a base station.

FIG. 7 is a diagram of a neural network model constituting an encoder and a decoder.

FIG. 8 is a sequence diagram illustrating details of processing in the wireless communication system according to the first embodiment of the present disclosure.

FIG. 9 is a sequence diagram illustrating details of processing in a wireless communication system according to a second embodiment of the present disclosure.

FIG. 10 is a sequence diagram illustrating details of processing in a wireless communication system according to a third embodiment of the present disclosure.

FIG. 11 is a diagram illustrating specifications of two AI/ML models constituting an encoder.

FIG. 12 is a diagram illustrating specifications of two AI/ML models constituting a decoder.

FIG. 13A is a sequence diagram illustrating details of processing in a wireless communication system according to a fourth embodiment of the present disclosure.

FIG. 13B is a sequence diagram illustrating details of processing in the wireless communication system according to the fourth embodiment of the present disclosure.

FIG. 13C is a sequence diagram illustrating details of processing in the wireless communication system according to the fourth embodiment of the present disclosure.

FIG. 14 is a diagram illustrating an example of a transmission method of channel status information for each subband.

FIG. 15 is a diagram illustrating an example of a transmission method of channel status information in the entire frequency band.

### MODE FOR CARRYING OUT THE INVENTION

Hereinafter, embodiments of the present disclosure will be described in detail with reference to the drawings. In the drawings, the same or corresponding elements will be denoted by the same reference signs, and detailed description thereof will be appropriately omitted.

### First Embodiment

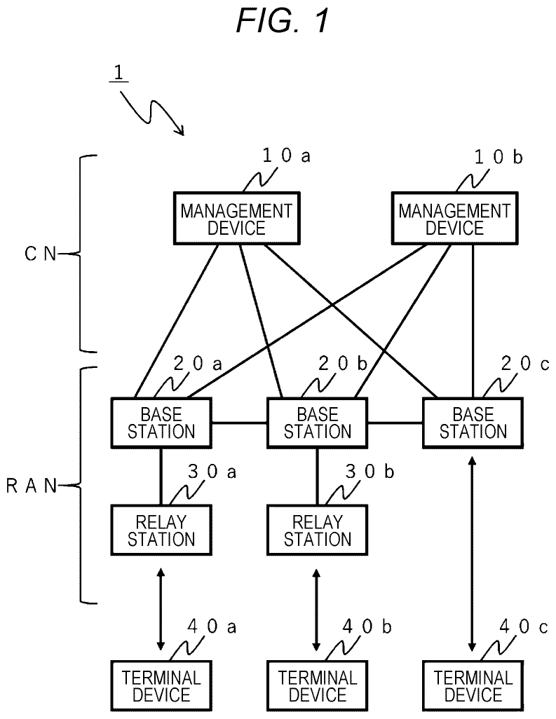

FIG. 1 is a diagram illustrating a configuration of a wireless communication system 1 according to a first embodiment of the present disclosure.

The wireless communication system 1 includes a management device 10, a base station 20, a relay station 30, and a terminal device 40. The wireless communication system 1 provides a radio network capable of mobile communication for a user by operating the wireless communication devices constituting the wireless communication system 1 in cooperation. The radio network of the first embodiment includes a radio access network RAN and a core network CN. In the first embodiment, the wireless communication device is a device having a function of wireless communication, and in the example of FIG. 1, the base station 20, the relay station 30, and the terminal device 40 correspond thereto.

The wireless communication system 1 may include a plurality of management devices 10, a plurality of base stations 20, a plurality of relay stations 30, and a plurality of terminal devices 40. In the example of FIG. 1, the wireless communication system 1 includes management devices 10a and 10b as the management device 10, and includes base stations 20a, 20b, and 20c as the base station 20. In addition, the wireless communication system 1 includes relay stations 30a and 30b as the relay stations 30, and includes terminal devices 40a, 40b, and 40c as the terminal devices 40.

Each wireless communication device in FIG. 1 may be considered as a device in a logical sense. That is, a part of each wireless communication device may be realized by a virtual machine (VM), a container, a docker, or the like, and they may be implemented on physically the same hardware.

The wireless communication system 1 may support a radio access technology (RAT) such as long term evolution (LTE) or new radio (NR). LTE and NR are a type of cellular wireless communication technology, and enable mobile communication of the terminal device 40 by arranging a plurality of areas covered by the base station 20 in cell shapes.

The radio access scheme of the wireless communication system 1 is not limited to LTE, NR, or the like, and may be another radio access scheme such as wideband code division multiple access (W-CDMA) or code division multiple access 2000 (cdma2000).

The base station 20 and the relay station 30 constituting the wireless communication system 1 may be ground stations or non-ground stations. The non-ground station may be a satellite station or an aircraft station. In a case where the non-ground station is a satellite station, the wireless communication system 1 may be a Bent-pipe (Transparent) type mobile satellite communication system.

In the first embodiment, a ground station (also referred to as a “ground base station”) refers to a base station (“relay station”) installed on the ground. Here, the “ground” is a ground in a broad sense including not only on land but also underground, above water, and underwater. Note that, in the following description, the description of “ground station” may be replaced with “gateway”.

The base station of LTE may be referred to as an evolved node B (eNodeB) or an eNB. The base station of NR may also be referred to as a gNodeB or a gNB. In LTE and NR, a terminal device (also referred to as a “mobile station” or a “terminal”) may be referred to as user equipment (UE).

In the first embodiment, the concept of the wireless communication device includes not only a portable moving body device (terminal device) such as a mobile terminal but also a device installed in a structure or a moving body. The structure or the moving body itself may be regarded as a wireless communication device. In addition, the concept of the wireless communication device includes not only the terminal device 40 but also the base station 20 and the relay station 30. The wireless communication device is a type of processing device or information processing device. The wireless communication device can also be referred to as a transmission device or a reception device.

Hereinafter, the configuration of each wireless communication device constituting the wireless communication system 1 will be specifically described. Note that the configuration of each wireless communication device described below is merely an example. The configuration of each wireless communication device may be different from the following configuration.

### (Configuration of Management Device)

The management device 10 is a device that manages a radio network. For example, the management device 10 is a device that manages communication of the base station 20. In a case where the core network CN is an evolved packet core (EPC), the management device 10 is, for example, a device having a function as a mobility management entity (MME). In a case where the core network CN is a 5G core network (5GC), the management device 10 is, for example, a device having a function as an access and mobility management function (AMF) and/or a session management function (SMF). However, the functions of the management device 10 are not limited to the MME, the AMF, and the SMF. In a case where the core network CN is 5GC, the management device 10 may be a device having a function as a network slice selection function (NSSF), an authentication server function (AUSF), or a unified data management (UDM). The management device 10 may be a device having a function as a home subscriber server (HSS).

The management device 10 may have a function of a gateway. In a case where the core network CN is the EPC, the management device 10 may have a function as a serving gateway (S-GW) or a packet data network gateway (P-GW). In a case where the core network CN is 5GC, the management device 10 may have a function as a user plane function (UPF). The management device 10 is not necessarily a device constituting the core network CN. In a case where the core network CN is a core network of wideband code division multiple access (W-CDMA) or code division multiple access 2000 (cdma2000), the management device 10 may be a device that functions as a radio network controller (RNC).

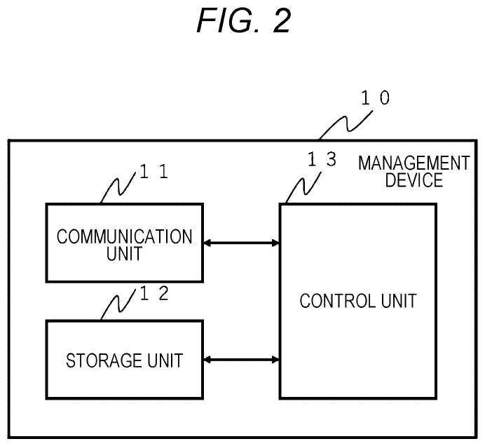

FIG. 2 is a diagram illustrating a configuration of the management device 10 according to the first embodiment. The management device 10 includes a communication unit 11, a storage unit 12, and a control unit 13. However, the configuration illustrated in FIG. 2 is a functional configuration, and the hardware configuration may be different from the functional configuration. Furthermore, the functions of the management device 10 may be statically or dynamically distributed and implemented in a plurality of physically separated configurations. The management device 10 may include a plurality of server devices.

The communication unit 11 is a communication interface for communicating with a wireless communication device (for example, the base station 20 or the relay station 30). The communication unit 11 may be a network interface or a device connection interface. The communication unit 11 may be a local area network (LAN) interface such as a network interface card (NIC), a universal serial bus (USB) host controller, or a USB interface configured by a USB port or the like. The communication unit 11 may be a wired interface or a wireless interface. The communication unit 11 functions as a communication means of the management device 10. The communication unit 11 is controlled by the control unit 13.

The storage unit 12 is a readable/writable storage device such as a dynamic random access memory (DRAM), a static random access memory (SRAM), a flash memory, or a hard disk. The storage unit 12 functions as a storage means of the management device 10. The storage unit 12 stores, for example, a connection state of the terminal device 40. The storage unit 12 stores a radio resource control (RRC) state and an EPS connection management (ECM) state or a 5G system connection management (CM) state of the terminal device 40. The storage unit 12 may function as a home memory that stores the position information of the terminal device 40.

The control unit 13 is a controller that controls each unit of the management device 10. The control unit 13 may be realized by, for example, a processor such as a central processing unit (CPU) or a micro processing unit (MPU). Specifically, the control unit 13 may be realized by a processor executing various programs stored in a storage device inside the management device 10 using a random access memory (RAM) or the like as a work area. The control unit 13 may be realized by an integrated circuit such as an application specific integrated circuit (ASIC) or a field programmable gate array (FPGA). Any of the CPU, the MPU, the ASIC, and the FPGA can be regarded as a controller.

### (Configuration of Base Station)

The base station 20 is a wireless communication device that performs wireless communication with the terminal device 40. The base station 20 may wirelessly communicate with the terminal device 40 via the relay station 30, or may directly wirelessly communicate with the terminal device 40.

The base station 20 is a device corresponding to a wireless base station (base station, Node B, eNB, gNB, or the like) or a radio access point. The base station 20 may be a wireless relay station. The base station 20 may be an optical extension device called a remote radio head (RRH). The base station 20 may be a receiving station such as a field pickup unit (FPU). The base station 20 may be an integrated access and backhaul (IAB) donor node or an IAB relay node that provides radio access lines and radio backhaul lines in time division multiplexing, frequency division multiplexing, or space division multiplexing.

The radio access technology used by the base station 20 may be a cellular communication technology. The radio access technology used by the base station 20 may be a wireless LAN technology. The radio access technology used by the base station 20 may be a low power wide area (LPWA) communication technology. However, the radio access technology used by the base station 20 is not limited thereto, and may be another radio access technology. The wireless communication used by the base station 20 may be wireless communication using millimeter waves. The wireless communication used by the base station 20 may be wireless communication using radio waves, or may be wireless communication using infrared rays or visible light, that is, optical radio.

The base station 20 may be able to perform non-orthogonal multiple access (NOMA) communication with the terminal device 40. The NOMA communication is communication (transmission, reception, or both) using a non-orthogonal resource. The base station 20 may be able to perform NOMA communication with another base station 20.

The base station 20 may be communicable with the core network CN via an interface between the base station 20 and the core network CN, for example, an SI interface. This interface may be wired or wireless. The base station 20 may be able to communicate with other base stations via an interface between base stations, for example, an X2 interface or the like. This interface may be wired or wireless.

The concept of the base station (also referred to as a “base station device”) includes not only a donor base station but also a relay base station (also referred to as a “relay station”). The concept of the base station includes not only a structure having a function of the base station but also a device installed in the structure.

The structure is, for example, a building such as a high-rise building, a house, a steel tower, a station facility, an airport facility, a harbor facility, or a stadium. The concept of the structure includes not only a building but also a construction (non-building structure) such as a tunnel, a bridge, a dam, a fence, and an iron pillar, and facilities such as a crane, a gate, and a windmill. The concept of the structure includes not only a structure on land (on the ground in a narrow sense) or underground, but also a structure above water such as a pier or a mega-float, and a structure under water such as a marine observation facility. The base station may also be referred to as an information processing device.

The base station 20 may be a fixed station or a wireless communication device configured to be movable, that is, a mobile station. The base station 20 may be a device installed in a moving body or may be a moving body itself. A relay station having mobility can be regarded as the base station 20 as a mobile station. A device originally having a mobility, such as a vehicle, an unmanned aerial vehicle (UAV) typified by a drone or the like, and a smartphone, which is equipped with at least a part of the functions of the base station can also be regarded as the base station 20 as a mobile station.

The moving body may be a mobile terminal such as a smartphone or a mobile phone. The moving body may be a moving body (for example, a vehicle such as an automobile, a bicycle, a bus, a truck, a motorcycle, a train, or a linear motor car) that moves on land (on the ground in a narrow sense) or a moving body (for example, the subway) that moves under the ground (for example, in the tunnel).

The moving body may be a moving body (for example, a ship such as a passenger ship, a cargo ship, or a hovercraft) that moves over water or a moving body (for example, submersible vehicles such as submersibles, submarines, or unmanned submersibles) that moves under water.

The moving body may be a moving body (for example, an aircraft such as an airplane, an airship, or a drone) that moves in the atmosphere.

The base station 20 may be a ground base station (ground station) installed on the ground. The base station 20 may be a base station arranged in a structure on the ground or may be a base station installed in a moving body moving on the ground. The base station 20 may be an antenna installed in a structure such as a building and a signal processing device connected to the antenna. The base station 20 may be a structure or a moving body itself. The “ground” is a ground in a broad sense including not only on land (on the ground in a narrow sense) but also underground, above water, and underwater. The base station 20 is not limited to a ground base station. In a case where the wireless communication system 1 is a satellite communication system, the base station 20 may be an aircraft station. From the perspective of a satellite station, an aircraft station located on the earth is a ground station.

The base station 20 is not limited to a ground station. The base station 20 may be a non-ground base station device (non-ground station) capable of floating in the air or space. The base station 20 may be an aircraft station or a satellite station.

The satellite station is a satellite station capable of floating outside the atmosphere. The satellite station may be a device mounted on a space vehicle such as an artificial satellite, or may be a space vehicle itself. The space vehicle is a moving body that moves outside the atmosphere. Examples of the space vehicle include artificial bodies such as artificial satellites, spacecraft, space stations, and probes.

The satellite serving as the satellite station may be any of a low earth orbiting (LEO) satellite, a medium earth orbiting (MEO) satellite, a geostationary earth orbiting (GEO) satellite, or a highly elliptical orbiting (HEO) satellite. The satellite station may be a device mounted on a low earth orbiting satellite, a medium earth orbiting satellite, a geostationary earth orbiting satellite, or a highly elliptical orbiting satellite.

The aircraft station is a wireless communication device capable of floating in the atmosphere such as an aircraft. The aircraft station may be a device mounted on an aircraft or the like, or may be an aircraft itself. The concept of the aircraft includes not only a heavy aircraft such as an airplane or a glider, but also a light aircraft such as a balloon or an airship. The concept of the aircraft includes not only heavy aircraft or light aircraft, but also rotorcraft such as helicopters or autogyros. The aircraft station or the aircraft on which the aircraft station is mounted may be an unmanned aerial vehicle such as a drone.

The concept of the unmanned aerial vehicle also includes an unmanned aircraft system (UAS) and a tethered UAS. The concept of the unmanned aerial vehicle includes lighter than air UAS (LTA) and heavier than air UAS (HTA). The concept of the unmanned aerial vehicle also includes high altitude UAS platforms (HAPs).

The size of the coverage of the base station 20 may be relatively large such as a macro cell or may be relatively small such as a pico cell. The size of the coverage of the base station 20 may be extremely small, such as a femto cell. The base station 20 may have a beamforming function. In the base station 20, a cell or a service area may be formed for each beam.

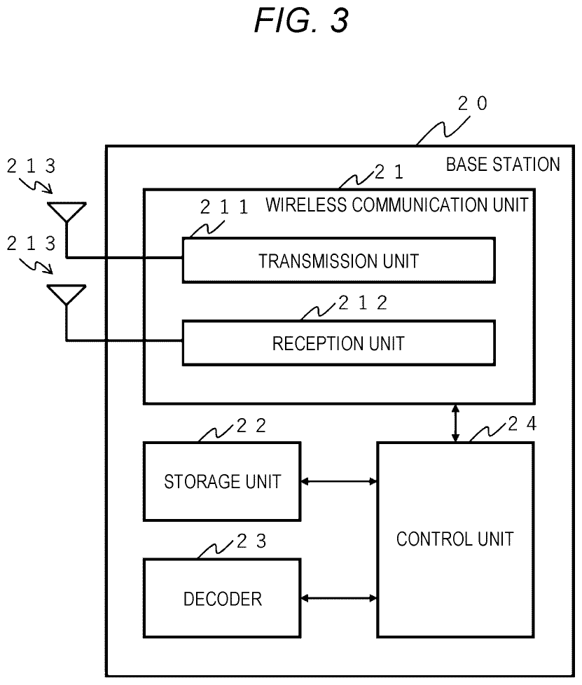

FIG. 3 is a diagram illustrating a configuration of the base station 20 according to the first embodiment. The base station 20 includes a wireless communication unit 21, a storage unit 22, a decoder 23, and a control unit 24. However, the configuration illustrated in FIG. 3 is a functional configuration, and the hardware configuration may be different from the functional configuration. Furthermore, the functions of the base station 20 may be implemented in a distributed manner in a plurality of physically separated configurations.

The wireless communication unit 21 is a signal processing unit for wirelessly communicating with other wireless communication devices (for example, the relay station 30, the terminal device 40, or another base station 20). The wireless communication unit 21 is controlled by the control unit 24. The wireless communication unit 21 corresponds to one or a plurality of radio access schemes. The wireless communication unit 21 may support both NR and LTE. The wireless communication unit 21 may support W-CDMA, cdma2000, and the like in addition to NR and LTE. The wireless communication unit 21 may support an automatic retransmission technology such as hybrid automatic repeat request (HARQ).

The wireless communication unit 21 includes a transmission unit 211, a reception unit 212, and an antenna 213. The wireless communication unit 21 may include a plurality of transmission units 211, a plurality of reception units 212, and a plurality of antennas 213. In a case where the wireless communication unit 21 supports a plurality of radio access schemes, each unit of the wireless communication unit 21 may be configured individually for each radio access scheme. The transmission unit 211 and the reception unit 212 may be individually configured by LTE and NR. The antenna 213 may include a plurality of antenna elements, for example, a plurality of patch antennas. The wireless communication unit 21 may have a beamforming function. The wireless communication unit 21 may have a polarization beamforming function using vertically polarized waves (V-polarized waves) and horizontally polarized waves (H-polarized waves).

The transmission unit 211 performs transmission processing of the downlink control information and the downlink data. As an example, first, the transmission unit 211 encodes the downlink control information and the downlink data input from the control unit 24 using an encoding scheme such as block encoding, convolutional encoding, turbo encoding, or the like. As the encoding, encoding using a polar code or encoding using a low density parity check code (LDPC code) may be performed.

Next, the transmission unit 211 modulates the encoded bits according to a predetermined modulation scheme such as BPSK, QPSK, 16QAM, 64QAM, or 256QAM. At this time, the signal points on the constellation do not necessarily have to be equidistant. That is, the constellation may be a non uniform constellation (NUC).

Next, the transmission unit 211 multiplexes the modulation symbol of each channel and the downlink reference signal and arranges the multiplexed symbols in a predetermined resource element. Next, the transmission unit 211 performs various types of signal processing on the multiplexed signal. As an example, the transmission unit 211 performs processing such as conversion into a frequency domain by fast Fourier transform, addition of a guard interval (cyclic prefix), generation of a baseband digital signal, conversion into an analog signal, quadrature modulation, up-conversion, removal of an extra frequency component, and power amplification. Finally, the signal generated by the transmission unit 211 is transmitted from the antenna 213.

The reception unit 212 processes the uplink signal received via the antenna 213. As an example, first, the reception unit 212 performs down-conversion, removal of an unnecessary frequency component, control of an amplification level, quadrature demodulation, conversion to a digital signal, removal of a guard interval (cyclic prefix), extraction of a frequency domain signal by fast Fourier transform, and the like on the uplink signal.

Next, the reception unit 212 separates uplink channels and uplink reference signals such as a physical uplink shared channel (PUSCH) and a physical uplink control channel (PUCCH) from the signals subjected to these processes. Next, the reception unit 212 demodulates the reception signal from the modulation symbol of the uplink channel according to a modulation scheme such as binary phase shift keying (BPSK) or quadrature phase shift keying (QPSK). The modulation scheme may be 16 quadrature amplitude modulation (QAM), 64QAM, 256QAM, or the like. At this time, the signal points on the constellation do not necessarily have to be equidistant. That is, the constellation may be a non-uniform constellation.

Next, the reception unit 212 performs decoding processing on the demodulated encoded bits of the uplink channel. Finally, the decoded uplink data and uplink control information are output to the control unit 24.

The antenna 213 is an antenna device that mutually converts a current and a radio wave. The antenna 213 may be configured by one antenna element, for example, one patch antenna. The antenna 213 may include a plurality of antenna elements, for example, a plurality of patch antennas. In a case where the antenna 213 includes a plurality of antenna elements, the wireless communication unit 21 may have a beamforming function. The wireless communication unit 21 may be configured to generate a directional beam by controlling directivity of a wireless signal using a plurality of antenna elements. The antenna 213 may be a dual-polarized antenna. In a case where the antenna 213 is a dual-polarized antenna, the wireless communication unit 21 may use vertically polarized waves (V-polarized waves) and horizontally polarized waves (H-polarized waves) when transmitting a wireless signal. The wireless communication unit 21 may control the directivity of the wireless signal transmitted using the vertically polarized wave and the horizontally polarized wave.

The storage unit 22 is a readable/writable storage device such as a DRAM, an SRAM, a flash memory, or a hard disk. The storage unit 22 functions as a storage means of the base station 20.

The decoder 23 is a decoder configured by an AI/ML model. The decoder 23 receives a second bit sequence or symbol sequence having an N-bit data amount as an input and decodes the second bit sequence or symbol sequence to restore and output a first bit sequence or symbol sequence having an M-bit data amount. The decoder 23 may be realized by a processor such as a CPU or an MPU. The decoder 23 may be realized by an integrated circuit such as an ASIC or an FPGA. A more detailed configuration of the decoder 23 will be described later with reference to FIG. 7.

The control unit 24 is a controller that controls each unit of the base station 20. The control unit 24 may be realized by a processor such as a CPU or an MPU. Specifically, the control unit 24 may be implemented by a processor executing various programs stored in a storage device inside the base station 20 using a RAM or the like as a work area. The control unit 24 may be realized by an integrated circuit such as an ASIC or an FPGA. Any of the CPU, the MPU, the ASIC, and the FPGA can be regarded as a controller. The control unit 24 may be realized by a graphics processing unit (GPU) in addition to or instead of the CPU.

Note that, in some embodiments, the base station 20 may be configured by a set of a plurality of physical or logical devices. As an example, the base station 20 of the first embodiment may be distinguished into a plurality of devices such as a baseband unit (BBU) and a radio unit (RU). The base station 20 may be interpreted as a set of the plurality of devices. In addition, the base station may be either a BBU or an RU, or may be both. The BBU and the RU may be connected by a predetermined interface such as an enhanced common public radio interface (eCPRI).

The RU may be referred to as a remote radio unit (RRU) or a radio DoT (RD). The RU may correspond to a gNB distributed unit (gNB-DU) described later. The BBU may correspond to a gNB central unit (gNB-CU) described later. The RU may be a device integrally formed with the antenna. An antenna of the base station 20, for example, an antenna integrally formed with an RU, may adopt an advanced antenna system and support MIMO or beamforming such as FD-MIMO. The antenna of the base station 20 may include, for example, 64 transmission antenna ports and 64 reception antenna ports.

The antenna mounted on the RU may be an antenna panel constituted by one or more antenna elements, and the RU may be mounted with one or more antenna panels. The RU may be equipped with two types of antenna panels: a horizontally polarized antenna panel and a vertically polarized antenna panel. The RU may be equipped with two types of antenna panels: a right-handed circularly polarized antenna panel and a left-handed circularly polarized antenna panel. The RU may be controlled by forming an independent beam for each antenna panel.

A plurality of base stations 20 may be connected to each other. One or a plurality of base stations 20 may be included in a radio access network (RAN). At this time, the base station 20 may be simply referred to as a RAN, a RAN node, an access network (AN), an AN node, or the like. The RAN in LTE may be referred to as an enhanced universal terrestrial RAN (EUTRAN). The RAN in NR may be referred to as NGRAN. The RAN in W-CDMA (UMTS) may be referred to as UTRAN.

The base station 20 in LTE may be referred to as an evolved node B (eNodeB) or an eNB. At this time, the EUTRAN includes one or a plurality of eNodeBs (eNBs). The base station 20 in NR may be referred to as a gNodeB or a gNB. At this time, the NGRAN includes one or a plurality of gNBs. The EUTRAN may include a gNB (en-gNB) connected to a core network (EPC) in an LTE communication system (EPS). The NGRAN may include an ng-eNB connected to a core network 5GC in a 5G communications system (5GS).

In a case where the base station 20 is an eNB, a gNB, or the like, the base station 20 may be referred to as 3GPP access. In a case where the base station 20 is a radio access point, the base station 20 may be referred to as non-3GPP access. The base station 20 may be an optical extension device called a remote radio head (RRH). In a case where the base station 20 is the gNB, the base station 20 may be a combination of the gNB-CU and the gNB-DU described above, or may be either the gNB-CU or the gNB-DU.

The gNB-CU hosts a plurality of upper layers (for example, RRC, SDAP, PDCP, and the like) in an access stratum for communication with the UE. The gNB-DU hosts a plurality of lower layers (for example, RLC, MAC, PHY, and the like) in an access stratum. Among the messages/information to be described later, the RRC signaling (semi-static notification) may be generated by the gNB-CU, and the MAC CE and the DCI (dynamic notification) may be generated by the gNB-DU. Alternatively, in the RRC configuration (semi-static notification), for example, some configurations such as IE: cellGroupConfig may be generated by the gNB-DU, and the remaining configurations may be generated by the gNB-CU. These configurations may be transmitted and received by an F1 interface to be described later.

The base station 20 may be configured to be able to communicate with other base stations. In a case where the plurality of base stations 20 is eNBs or a combination of an eNB and an en-gNB, these base stations 20 may be connected by an X2 interface. In a case where the plurality of base stations 20 is gNBs or a combination of a gn-eNB and a gNB, these base stations 20 may be connected by an Xn interface. In a case where the plurality of base stations 20 is a combination of the gNB-CU and the gNB-DU, these base stations 20 may be connected by the above-described F1 interface. A message/information (for example, RRC signaling, MAC control element (MAC CE), DCI, or the like) to be described later may be transmitted between the plurality of base stations 20 via, for example, the X2 interface, the Xn interface, the F1 interface, or the like.

The cell provided by the base station 20 may be referred to as a serving cell. The concept of the serving cell includes a primary cell (PCell) and a secondary cell (SCell). In a case where the dual connectivity is provided to the terminal device 40, the PCell provided by the master node (MN) and 0 or one or more SCells may be referred to as a master cell group. Examples of the dual connectivity include EUTRA-EUTRA dual connectivity, EUTRA-NR dual connectivity (ENDC), EUTRA-NR dual connectivity with 5GC, NR-EUTRA dual connectivity (NEDC), and NR-NR dual connectivity.

The serving cell may include a primary secondary cell or primary SCG Cell (PSCell). In a case where the dual connectivity is provided to the terminal device 40, the PSCell provided by a secondary node (SN) and 0 or 1 or more SCells may be referred to as a secondary cell group (SCG). Unless specially configured (for example, PUCCH on SCell), the physical uplink control channel (PUCCH) is transmitted by the PCell and the PSCell but not by the SCell. The radio link failure is detected by the PCell and the PSCell, but is not detected by the SCell (does not need to be detected). As described above, since the PCell and the PSCell play a special role in the serving cell, they are also referred to as a special cell (SpCell).

One downlink component carrier and one uplink link component carrier may be associated with one cell. The system bandwidth corresponding to one cell may be divided into a plurality of bandwidth parts (BWPs). At this time, one or a plurality of BWPs may be set in the terminal device 40, and one BWP may be used as an active BWP for the terminal device 40. A radio resource that can be used by the terminal device 40, for example, a frequency band, a numerology (subcarrier spacing), or a slot format (slot configuration) may be different for each cell, each component carrier, or each BWP.

### (Configuration of Relay Station)

The relay station 30 is a wireless communication device serving as a repeater of the base station 20. The relay station 30 is a type of base station. The relay station 30 is a type of information processing device. The relay station 30 can also be referred to as a relay base station.

The relay station 30 may be able to perform NOMA communication with the terminal device 40. The relay station 30 relays communication between the base station 20 and the terminal device 40. The relay station 30 may be able to perform wireless communication with another relay station 30 and the base station 20. The relay station 30 may be a ground station device or a non-ground station device. The relay station 30 constitutes a radio access network RAN together with the base station 20.

The relay station 30 may be a fixed device, a movable device, or a floating device. The size of the coverage of the relay station 30 is not limited to a specific size. The cell covered by the relay station 30 may be a macro cell, a micro cell, or a small cell.

The relay station 30 is not limited to a mounted device as long as the function of relay is satisfied. The relay station 30 may be mounted on a terminal device such as a smartphone, may be mounted on an automobile, a train, a rickshaw, or the like, may be mounted on a balloon, an airplane, a drone, or the like, or may be mounted on a home appliance such as a television, a game machine, an air conditioner, a refrigerator, or a lighting fixture.

The configuration of the relay station 30 may be similar to the configuration of the base station 20 described above. Similarly to the base station 20 described above, the relay station 30 may be a device installed in a moving body or may be a moving body itself. As described above, the moving body may be a mobile terminal such as a smartphone or a mobile phone. The moving body may be a moving body that moves on land (on the ground in a narrow sense) or may be a moving body that moves under the ground. The moving body may be a moving body that moves over water or may be a moving body that moves under water. The moving body may be a moving body that moves inside the atmosphere or may be a moving body that moves outside the atmosphere. The relay station 30 may be a ground station device or a non-ground station device. The relay station 30 may be an aircraft station, a satellite station, or the like.

Similarly to the base station 20, the size of the coverage of the relay station 30 may be large such as a macro cell or small such as a pico cell. The size of the coverage of the relay station 30 may be extremely small, such as a femto cell. The relay station 30 may have a beamforming function. In the relay station 30, a cell or a service area may be formed for each beam.

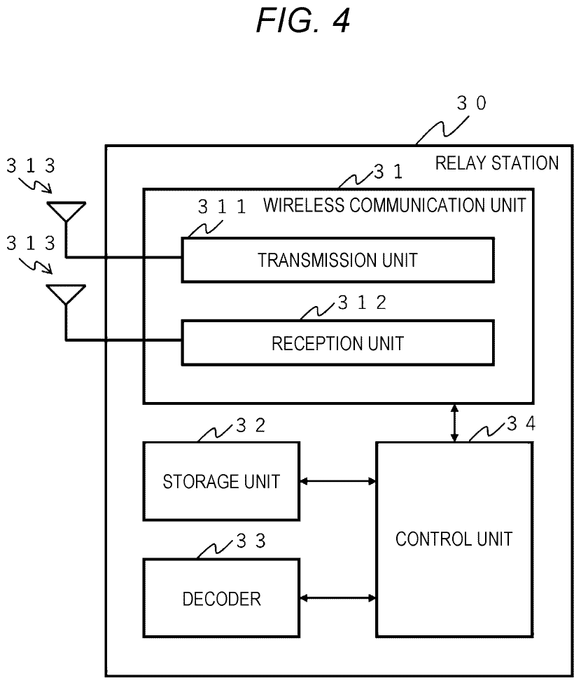

FIG. 4 is a diagram illustrating a configuration of the relay station 30 according to the first embodiment. The relay station 30 includes a wireless communication unit 31, a storage unit 32, a decoder 33, and a control unit 34. However, the configuration illustrated in FIG. 4 is a functional configuration, and the hardware configuration may be different from this. Furthermore, the functions of the relay station 30 may be implemented in a distributed manner in a plurality of physically separated configurations.

The wireless communication unit 31 is a signal processing unit for wirelessly communicating with other wireless communication devices (for example, the base station 20, the terminal device 40, or another relay station 30). The wireless communication unit 31 corresponds to one or a plurality of radio access schemes. The wireless communication unit 31 may support both NR and LTE. The wireless communication unit 31 may support W-CDMA, cdma3000, and the like in addition to NR and LTE.

The wireless communication unit 31 includes a transmission unit 311, a reception unit 312, and an antenna 313. The wireless communication unit 31 may include a plurality of transmission units 311, a plurality of reception units 312, and a plurality of antennas 313. In a case where the wireless communication unit 31 supports a plurality of radio access schemes, each unit of the wireless communication unit 31 may be configured individually for each radio access scheme. The transmission unit 311 and the reception unit 312 may be individually configured by LTE and NR. The configurations of the transmission unit 311, the reception unit 312, and the antenna 313 may be similar to the configurations of the transmission unit 211, the reception unit 212, and the antenna 213 of the base station 20 described above. The wireless communication unit 31 may have a beamforming function similarly to the wireless communication unit 21 of the base station 20.

The storage unit 32 is a readable/writable storage device such as a DRAM, an SRAM, a flash memory, or a hard disk. The storage unit 32 functions as a storage means of the relay station 30.

The decoder 33 is a decoder configured by an AI/ML model. The decoder 33 receives a second bit sequence or symbol sequence having an N-bit data amount as an input and decodes the second bit sequence or symbol sequence to restore and output a first bit sequence or symbol sequence having an M-bit data amount. The configuration and function of the decoder 33 may be similar to the configuration and function of the decoder 23 of the base station 20 described above.

The control unit 34 is a controller that controls each unit of the relay station 30. The control unit 34 may be realized by a processor such as a CPU or an MPU. Specifically, the control unit 34 may be implemented by a processor executing various programs stored in a storage device inside the relay station 30 using a RAM or the like as a work area. The control unit 34 may be realized by an integrated circuit such as an ASIC or an FPGA. Any of the CPU, the MPU, the ASIC, and the FPGA can be regarded as a controller. The control unit 34 may be realized by a GPU in addition to or instead of the CPU.

Note that the relay station 30 may be an IAB relay node. The relay station 30 operates as an IAB-mobile termination (MT) for an IAB donor node that provides backhaul, and operates as an IAB-distributed unit (DU) for the terminal device 40 that provides access. The IAB donor node may be, for example, the base station 20, and operates as an IAB-central unit (CU).

### (Configuration of Terminal Device)

The terminal device 40 is a wireless communication device that performs wireless communication with another wireless communication device (for example, the base station 20, the relay station 30, another terminal device 40, or the like). The terminal device 40 may be a mobile phone, a smart device (smartphone or tablet), a personal digital assistant (PDA), a personal computer, or the like. The terminal device 40 may be a device such as a business camera having a communication function. The terminal device 40 may be a motorcycle, a moving relay vehicle, or the like on which a communication device such as a field pickup unit (FPU) is mounted. The terminal device 40 may be a machine to machine (M2M) device, an internet of things (IoT) device, or the like.

The terminal device 40 may be able to perform NOMA communication with the base station 20. The terminal device 40 may be able to use an automatic retransmission technology such as HARQ when communicating with the base station 20. The terminal device 40 may be able to perform sidelink communication with another terminal device 40. The terminal device 40 may be able to use an automatic retransmission technology such as HARQ when performing sidelink communication. The terminal device 40 may be able to perform NOMA communication when performing sidelink communication with another terminal device 40. The terminal device 40 may be able to perform LPWA communication with other wireless communication devices such as the base station 20. The wireless communication used by the terminal device 40 may be wireless communication using millimeter waves. The wireless communication used by the terminal device 40 may be wireless communication using radio waves including sidelink communication, or may be wireless communication using infrared rays or visible light, that is, optical radio.

The terminal device 40 may be a movable wireless communication device, that is, a moving body device. The terminal device 40 may be a wireless communication device installed in a moving body or may be a moving body itself. The terminal device 40 may be a vehicle that moves on a road such as an automobile, a bus, a truck, or a motorcycle, or may be a wireless communication device mounted on the vehicle. The moving body may be a mobile terminal, or may be a moving body that moves on land (on the ground in a narrow sense), underground, above water, or underwater. The moving body may be a moving body that moves inside the atmosphere, such as a drone or a helicopter, or may be a moving body that moves outside the atmosphere, such as an artificial satellite.

The terminal device 40 may be able to communicate by being connected to a plurality of base stations 20 or a plurality of cells at the same time. In a case where one base station 20 supports a communication area via a plurality of cells (for example, pCell or sCell), the plurality of cells can be bundled to communicate between the base station 20 and the terminal device 40 by a carrier aggregation (CA) technology, a dual connectivity (DC) technology, a multi-connectivity (MC) technology, or the like. Alternatively, the terminal device 40 and the plurality of base stations 20 can communicate with each other by a coordinated transmission and reception (COMP: Coordinated Multi-Point Transmission and Reception) technology via cells of different base stations 20.

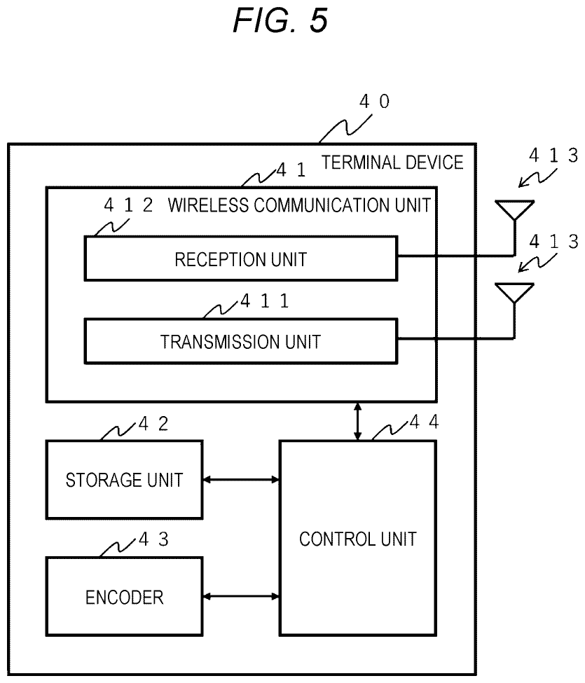

FIG. 5 is a diagram illustrating a configuration of the terminal device 40 according to the first embodiment. The terminal device 40 includes a wireless communication unit 41, a storage unit 42, an encoder 43, and a control unit 44. However, the configuration illustrated in FIG. 5 is a functional configuration, and the hardware configuration may be different from this. Furthermore, the functions of the terminal device 40 may be implemented in a distributed manner in a plurality of physically separated configurations.

The wireless communication unit 41 is a signal processing unit for wirelessly communicating with other wireless communication devices (for example, the base station 20, the relay station 30, or another terminal device 40). The wireless communication unit 41 is controlled by the control unit 44. The wireless communication unit 41 includes a transmission unit 411, a reception unit 412, and an antenna 413. The configurations of the wireless communication unit 41, the transmission unit 411, the reception unit 412, and the antenna 413 may be similar to the configurations of the wireless communication unit 21, the transmission unit 211, the reception unit 212, and the antenna 213 of the base station 20. The wireless communication unit 41 may have a beamforming function similarly to the wireless communication unit 21 of the base station 20.

The storage unit 42 is a readable/writable storage device such as a DRAM, an SRAM, a flash memory, or a hard disk. The storage unit 42 functions as a storage means of the terminal device 40.

The encoder 43 is an encoder configured by an AI/ML model. The encoder 43 receives a first bit sequence or symbol sequence having an M-bit data amount as an input, and encodes the first bit sequence or symbol sequence to output a second bit sequence or symbol sequence having an N-bit data amount. The encoder 43 may be realized by a processor such as a CPU or an MPU. The encoder 43 may be realized by an integrated circuit such as ASIC or FPGA. A more detailed configuration of the encoder 43 will be described later with reference to FIG. 7.

The control unit 44 is a controller that controls each unit of the terminal device 40. The control unit 44 may be realized by a processor such as a CPU or an MPU. Specifically, the control unit 44 may be realized by a processor executing various programs stored in a storage device inside the terminal device 40 using a RAM or the like as a work area. The control unit 44 may be realized by an integrated circuit such as an ASIC or an FPGA. Any of the CPU, the MPU, the ASIC, and the FPGA can be regarded as a controller. The control unit 44 may be realized by a GPU in addition to or instead of the CPU.

### (Detailed Configuration of Terminal Device and Base Station)

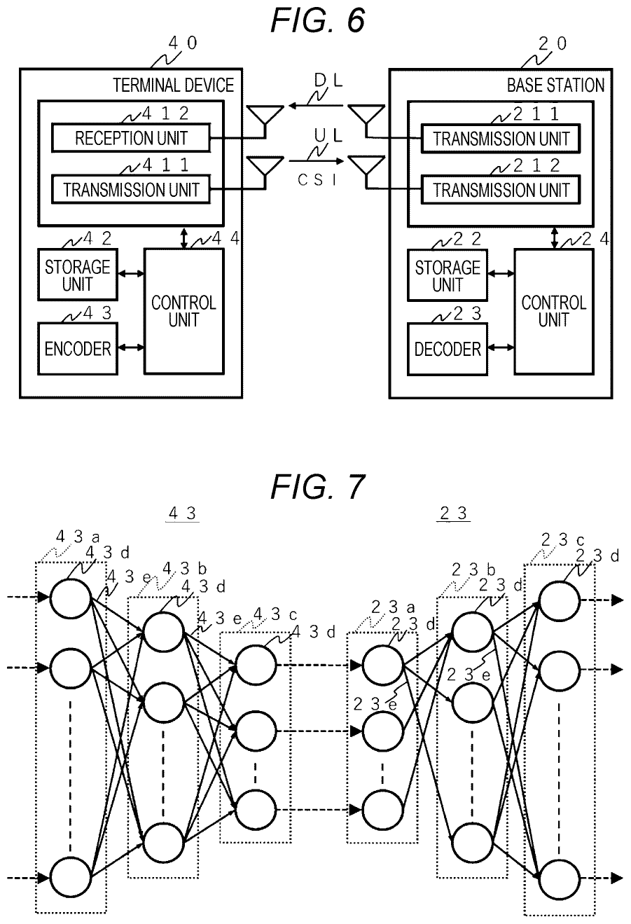

As illustrated in FIG. 6, in the wireless communication system 1 according to the first embodiment, downlink (DL) channel status information CSI is transmitted from the terminal device 40 to the base station 20. At this time, the channel status information CSI is encoded by the terminal device 40 on the transmission side and decoded by the base station 20 on the reception side. Here, encoding and decoding are signal processing functions for performing arbitrary signal processing, and may be terms other than encoding and decoding, and encoding and decoding may be signal processing other than the data compression function as well as the data compression function. Hereinafter, examples will be described using terms such as encoding, encoder, decoding, and decoder, but other terms may be used. Further, the channel status information CSI of the downlink DL may be transmitted from the terminal device 40 to the relay station 30. That is, the technology according to the present disclosure can be applied to the base station 20 and the relay station 30 exactly in a similar manner.

The channel status information CSI can include one or a plurality of pieces of information such as a channel quality indicator (CQI), a precoding matrix indicator (PMI), a CSI-RS resource indicator (CRI), an SS/PBCH resource block indicator (SSBRI), a layer indicator (LI), a rank indicator (RI), and reference signal received power (L1-RSRP). Further, in the present embodiment, the present invention is not limited to the channel status information CSI, and the present invention may be implemented on information other than the channel status information CSI, such as the amount of other cell interference and the position estimation information.

Furthermore, whether or not to encode and transmit each of these pieces of information may be selected. For example, PMI is encoded and transmitted, and RI is not encoded and transmitted as it is. At this time, which information is encoded may be determined in advance as a specification, or the notification of which information is encoded may be dynamically provided by using signaling or the like from the base station 20 to the terminal device 40.

As described above, the terminal device 40 includes the transmission unit 411, the reception unit 412, the storage unit 42, the encoder 43 configured by the AI/ML model, and the control unit 44. Furthermore, the base station 20 includes the transmission unit 211, the reception unit 212, the storage unit 22, the decoder 23 configured by the AI/ML model, and the control unit 24. However, the configuration illustrated in FIG. 6 is a functional configuration of the terminal device 40 and the base station 20, and may be different from an actual hardware configuration or software configuration.

Furthermore, the encoder 43 and the decoder 23 configured by the AI/ML model in the uplink (UL) are provided in FIG. 6, but the encoder 43 and the decoder 23 may be similarly provided for links other than the uplink, such as the downlink DL and the sidelink (SL). Hereinafter, an embodiment will be described by taking the uplink UL as an example, but the present invention can be similarly applied to links other than the uplink, such as the downlink DL and the sidelink SL.

The transmission unit 411 of the terminal device 40 transmits various types of control information and data to the base station 20 via the uplink UL. The reception unit 412 of the terminal device 40 receives various types of control information and data from the base station 20 via the downlink DL.

The encoder 43 of the terminal device 40 receives the channel status information CSI of the downlink DL having the M-bit data amount calculated by the control unit 44 as an input, encodes the channel status information CSI, and outputs encoded data having the N-bit data amount. However, in the first embodiment, M and N are positive numbers, and N<M. In addition, hereinafter, the original data input to the encoder 43 will be referred to as “RAW data” or “first bit string or symbol string”. Furthermore, the encoded data output from the encoder 43 is also referred to as “second bit string or symbol string”.

The transmission unit 211 of the base station 20 transmits various types of control information and data to the terminal device 40 via the downlink DL. The reception unit 212 of the base station 20 receives various types of control information and data from the terminal device 40 via the uplink UL.

The decoder 23 of the base station 20 receives the encoded data having the N-bit data amount received from the terminal device 40 as an input, and decodes the encoded data to restore and output the channel status information CSI of the downlink DL having the M-bit data amount.

Since N<M in the first embodiment, the encoder 43 of the terminal device 40 can be interpreted as a compressor that compresses M-bit data into N bits. Similarly, the decoder 23 of the base station 20 can be interpreted as a decompressor that restores M-bit data from N-bit data. Further, the RAW data input to the encoder 43 can be interpreted as data before the important data is extracted, and the encoded data output from the encoder 43 can be interpreted as data after the important data is extracted. However, the technology according to the present disclosure does not exclude the case of N & M. The technology according to the present disclosure can be applied to any communication system including an encoder and a decoder configured by an AI/ML model.

The AI/ML model constituting the encoder 43 and the decoder 23 is a model such as a neural network model obtained by machine learning or deep learning. For example, a neural network model as illustrated in FIG. 7 can be used as the AI/ML model.

In FIG. 7, the neural network model constituting the encoder 43 includes an input layer 43a, a hidden layer 43b, and an output layer 43c. Note that, although only one hidden layer 43b is illustrated in FIG. 7, a plurality of hidden layers 43b may be provided. The neural network model including the plurality of hidden layers 43b is also referred to as a deep neural network model, a deep learning model, or the like. The input layer 43a includes M nodes 43d. The hidden layer 43b includes a plurality of nodes 43d. The output layer 43c includes N nodes 43d. Each node 43d of the previous layer and each node 43d of the subsequent layer are connected via an edge 43e. Each node 43d has a linear or nonlinear function called an activation function, and each edge 43e is weighted.

Each bit of the RAW data of the channel status information CSI having the M-bit data amount is input to each node 43d included in the input layer 43a of the encoder 43. Each bit of encoded data having an N-bit data amount is output from each node 43d included in the output layer 43c of the encoder 43.

Similarly, the neural network model constituting the decoder 23 includes an input layer 23a, a hidden layer 23b, and an output layer 23c. However, similarly to the case of the encoder 43, a plurality of hidden layers 23b may be provided. The input layer 23a includes N nodes 23d. The hidden layer 23b includes a plurality of nodes 23d. The output layer 23c includes M nodes 23d. Each node 23d of the previous layer and each node 23d of the subsequent layer are connected via an edge 23e. Each node 23d has a linear or nonlinear function called an activation function, and each edge 23e is weighted.

Each bit of encoded data having an N-bit data amount is input to each node 23d included in the input layer 23a of the decoder 23. Each bit of the restored channel status information CSI having the M-bit data amount is output from each node 23d included in the output layer 23c of the decoder 23.

Note that, instead of the neural network model as illustrated in FIG. 7, another neural network model can be used. For example, a convolutional neural network (CNN), a recurrent neural network (RNN), a long short-term memory (LSTM), or the like may be used. Alternatively, these models may be used in series or in combination in parallel.

In a state where the encoder 43 of the terminal device 40 and the decoder 23 of the base station 20 are sufficiently trained and the both function correctly, the RAW data input to the encoder 43 and the decoded data output from the decoder 23 completely coincide with each other or coincide with each other within an allowable error range. Here, the allowable error range means that, for example, if high-order bits with high importance are matched, even if low-order bits with low importance are different, the allowable error range is set, or if bits of fields with high importance are matched, even if bits of fields with low importance are different, the allowable error range is set, or the like.

However, as described above, when the training of the encoder 43 of the terminal device 40 is insufficient, there is a possibility that the correctly encoded data is not transmitted to the base station 20. In this case, the decoder 23 of the base station 20 cannot correctly restore the original data.

In order to cope with this problem, in the first embodiment, the terminal device 40 is configured to be able to transmit both the encoded data and the RAW data when transmitting the channel status information CSI of the downlink DL to the base station 20. Then, the terminal device 40 normally transmits the encoded data to the base station 20, and in a case where “an aperiodic transmission execution notification of RAW data” is received from the base station 20, dynamically transmits the RAW data of the channel status information CSI aperiodically, that is, at a timing when the transmission execution notification is received, to the base station 20.

The base station 20 compares the channel status information CSI restored by decoding the encoded data received from the terminal device 40 with the RAW data of the channel status information CSI received from the terminal device 40, and determines whether or not the both completely match each other or whether or not the both match within an allowable error range, thereby verifying whether or not the data received from the terminal device 40 is correctly encoded.

### (Details of Processing of Wireless Communication System)

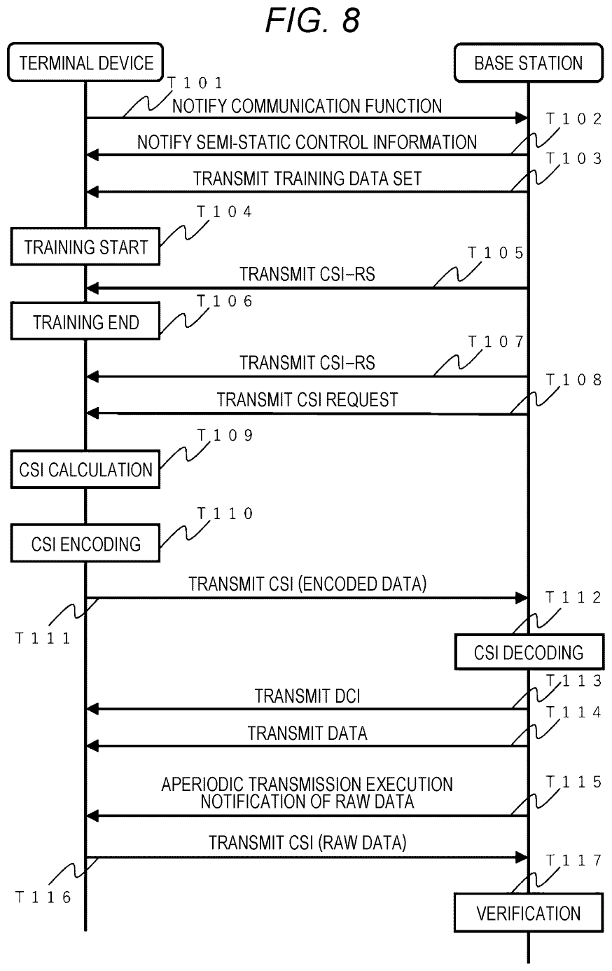

Hereinafter, details of processing in the wireless communication system 1 according to the first embodiment will be described with reference to a sequence diagram of FIG. 8. However, in the sequence diagram of FIG. 8, the AI/ML model constituting the decoder 23 of the base station 20 will be described on the assumption that sufficient training is performed in advance.

First, the transmission unit 411 of the terminal device 40 notifies the base station 20 of its own communication function (Capability) (T101). The communication function includes a function related to the technology according to the first embodiment. Specifically, the function is a function of transmitting both encoded data and RAW data, and a function of transmitting RAW data aperiodically.

The transmission unit 211 of the base station 20 notifies the terminal device 40 of semi-static control information related to the technology according to the present first embodiment (T102). When the channel status information CSI of the downlink DL is transmitted from the terminal device 40 to the base station 20, the semi-static control information normally includes information instructing transmission of encoded data and aperiodic transmission of RAW data in a case where an aperiodic transmission execution notification of RAW data is received.

Next, the transmission unit 211 of the base station 20 transmits a training data set for training the AI/ML model constituting the encoder 43 of the terminal device 40 to the terminal device 40 (T103). Each training data includes RAW data of downlink DL channel status information CSI created in advance, and encoded data as a correct answer label corresponding to the RAW data. As described above, the RAW data of the downlink DL channel status information CSI has an M-bit data amount, and the encoded data corresponding thereto has an N-bit data amount.

When the above-described training data set is received by the reception unit 412 of the terminal device 40, the control unit 44 of the terminal device 40 starts training of the AI/ML model constituting the encoder 43 using the received training data set (T104).

As described above, the AI/ML model constituting the encoder 43 is a neural network model. Various known methods including an error back-propagation method and the like can be used for training the neural network model. In the course of training the neural network model constituting the encoder 43, the weight of each edge 43e included in the neural network model is updated, and the data output from the encoder 43 approaches data that can be correctly restored in the decoder 23 of the base station 20. In other words, the weight of each edge 43e included in the neural network model constituting the encoder 43 is updated such that data that is correctly restored in the decoder 23 of the base station 20 is output.

Note that the base station 20 transmits a channel status estimation reference signal CSI-RS (Channel Status Information-Reference Signal) while the terminal device 40 is training (T105), but the terminal device 40 may not estimate the channel status during the training. Alternatively, the terminal device 40 may use the reception information for training. For example, the channel status indicated by the reception information may be preferentially trained so as to improve the encoding accuracy. The terminal device 40 may end the training in a case where a training end condition is satisfied. For example, the end condition may be that a predetermined period has elapsed from the start of the training. Alternatively, the accuracy of the model may be calculated on the basis of the training data set (for example, training data not used for training), and the calculated accuracy reaching a threshold value may be set as the end condition. Alternatively, the end condition may be that a training end instruction is transmitted from the base station 20 to the terminal device 40, and the terminal device 40 receives the training end instruction.

When the training of the AI/ML model constituting the encoder 43 is completed (T106), the channel status information CSI of the downlink DL can be transmitted from the terminal device 40 to the base station 20 as encoded data.

The transmission unit 211 of the base station 20 transmits a reference signal CSI-RS for downlink DL channel status estimation to the terminal device 40 (T107), and then transmits a downlink DL channel status information CSI transmission request to the terminal device 40 (T108).

When this transmission request is received by the reception unit 412 of the terminal device 40, the control unit 34 of the terminal device 40 calculates the channel status information CSI of the downlink DL having the M-bit data amount on the basis of the reference signal CSI-RS for downlink DL channel status estimation previously received at T107 (T109).

When the RAW data of the downlink DL channel status information CSI having the M-bit data amount is input to the encoder 43, encoded data having the N-bit data amount is output from the encoder 43 (T110). The transmission unit 411 of the terminal device 40 transmits the encoded data having the N-bit data amount to the base station 20 (T111).

When the encoded data having the N-bit data amount is received by the reception unit 212 of the base station 20 and input to the decoder 23, the channel status information CSI of the downlink DL having the M-bit data amount is restored and output from the decoder 23 (T112). The control unit 24 of the base station 20 can estimate the channel status of the downlink DL from the base station 20 to the terminal device 40 on the basis of the restored channel status information CSI.

The control unit 24 of the base station 20 performs scheduling of transmission via the downlink DL from the base station 20 to the terminal device 40 on the basis of the estimation result of the channel status of the downlink DL. The transmission unit 211 of the base station transmits downlink control information DCI including a result of the scheduling to the terminal device 40 (T113), and then performs data transmission to the terminal device 40 via a physical downlink shared channel (PDSCH) (T114). Note that the above-described downlink control information DCI transmitted at T113 may include information related to the technology according to the first embodiment.

Next, the transmission unit 211 of the base station 20 transmits an aperiodic transmission execution notification of the RAW data to the terminal device 40 (T115). Such a transmission execution notification can be transmitted by being included in, for example, data or the like flowing through DCI, MAC-control element (MAC-CE), or PDSCH.

When the reception unit 412 of the terminal device 40 receives the aperiodic transmission execution notification of the RAW data, the transmission unit 411 of the terminal device 40 dynamically transmits the RAW data of the channel status information CSI of the downlink DL having the M-bit data amount previously calculated at T109 to the base station 20 at the timing of receiving the aperiodic transmission execution notification, that is, the aperiodic transmission execution notification (T116).

When the RAW data of the downlink DL channel status information CSI having the M-bit data amount is received by the reception unit 212 of the base station 20, the control unit 24 of the base station 20 verifies whether or not the data previously received from the terminal device 40 at T111 is correctly encoded on the basis of the comparison between the RAW data and the data previously decoded at T112 (T117).

Specifically, the control unit 24 of the base station 20 determines that the data previously received from the terminal device 40 at T111 is correctly encoded in a case where the RAW data completely matches the previously decoded data or matches the previously decoded data within an allowable error range. On the other hand, the control unit 24 of the base station 20 determines that the data previously received from the terminal device 40 at T111 is not correctly encoded in a case where the RAW data does not completely match the previously decoded data or does not match the previously decoded data even within an allowable error range.

As described above, in the wireless communication system 1 according to the first embodiment of the present disclosure, the terminal device 40 as the transmission device includes the encoder 43 configured by the AI/ML model, and the base station 20 as the reception device includes the decoder 23 configured by the AI/ML model. The terminal device 40 can transmit both the encoded data and the RAW data to the base station 20.

The terminal device 40 normally transmits the encoded data to the base station 20, and aperiodically transmits the RAW data to the base station 20 in a case where an aperiodic transmission execution notification of the RAW data is received from the base station 20.

The control unit 24 of the base station 20 can verify whether or not the data received from the terminal device 40 is correctly encoded on the basis of the comparison between the RAW data and the previously decoded data. Then, by re-training the encoder 43 of the terminal device 40 as necessary on the basis of the verification result, the accuracy of the encoder 43 of the terminal device 40 can be improved.

Note that, in the first embodiment described above, the terminal device 40 normally transmits encoded data to the base station 20, and in a case where an aperiodic transmission execution notification of RAW data is received from the base station 20, aperiodically transmits the RAW data to the base station 20. Alternatively, as a first modification, the terminal device 40 may normally transmit RAW data to the base station 20, and may aperiodically transmit encoded data to the base station 20 in a case where an aperiodic transmission execution notification of the encoded data is received from the base station 20.

Alternatively, as a second modification, in conjunction with the aperiodic transmission of the channel status information CSI from the terminal device 40 to the base station 20, the signal transmitted and received at this time may include an aperiodic transmission execution notification of RAW data or encoded data. For example, instead of transmitting the aperiodic transmission execution notification of the RAW data from the base station 20 to the terminal device 40 at T115 in FIG. 8, the aperiodic transmission execution notification of the RAW data or the encoded data may be included in the aperiodic transmission request of the channel status information CSI transmitted from the base station 20 to the terminal device 40 at T108 in FIG. 8.

Furthermore, whether to transmit RAW data or encoded data may be determined on the terminal device 40 side instead of being explicitly designated on the base station 20 side. For example, in a case where it is determined that more detailed channel status information CSI needs to be transmitted on the basis of quality of service (QOS) or the like, the terminal device 40 may encode and transmit channel status information CSI having a large amount of data. Alternatively, the terminal device 40 may determine whether to transmit RAW data or encoded data on the basis of information of a resource or a sequence including the reference signal CSI-RS for channel status estimation.

Alternatively, as a third modification, the terminal device 40 may always transmit RAW data or encoded data, for example, in a specific time slot.

### Second Embodiment

Next, a second embodiment of the present disclosure will be described. In the first embodiment described above, the “aperiodic transmission execution notification of the RAW data” is transmitted from the base station 20 to the terminal device 40. On the other hand, in the second embodiment, “semi-persistent transmission execution notification of RAW data” is transmitted from the base station 20 to the terminal device 40. Upon receiving this, the terminal device 40 transmits the RAW data of the channel status information CSI to the base station 20 in a semi-persistent manner. Here, the semi-persistent transmission means that the RAW data is transmitted at a predetermined cycle with the reception of the transmission execution notification as a trigger.

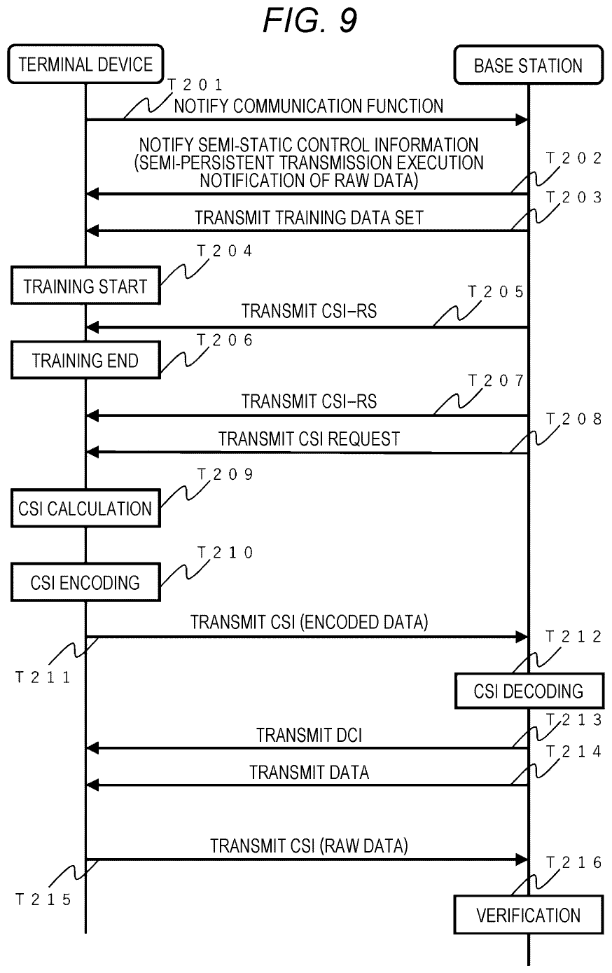

Hereinafter, details of processing in the wireless communication system 1 according to the second embodiment will be described with reference to a sequence diagram of FIG. 9. However, similarly to the first embodiment described above, in the sequence diagram of FIG. 9, the AI/ML model constituting the decoder 23 of the base station 20 will be described on the assumption that sufficient training is performed in advance.

First, the transmission unit 411 of the terminal device 40 notifies the base station 20 of its own communication function (T201). The communication function includes a function related to the technology according to the second embodiment. Specifically, it is a function of transmitting both encoded data and RAW data, and a function of transmitting RAW data in a semi-persistent manner.

The transmission unit 211 of the base station 20 notifies the terminal device 40 of semi-static control information related to the technology according to the present second embodiment (T202). The semi-static control information includes a semi-persistent transmission execution notification of the RAW data. The semi-persistent transmission execution notification of the RAW data normally instructs transmission of encoded data and transmission of the RAW data at a predetermined cycle when transmitting the channel status information CSI of the downlink DL from the terminal device 40 to the base station 20. Here, the predetermined cycle may be included in the transmission execution notification and the notification may be provided, or may be included in another signal such as radio resource control (RRC) signaling and the notification may be provided.

Subsequent processing from T203 to T212 is similar to the processing from T103 to T112 in FIG. 8 according to the first embodiment described above.

Next, the transmission unit 211 of the base station 20 transmits downlink control information DCI including a result of the transmission scheduling to the terminal device 40 (T213), and then, performs data transmission to the terminal device 40 via the PDSCH (T214). Note that the above-described downlink control information DCI transmitted at T213 may include information related to the technology according to the second embodiment.

As part of the semi-persistent transmission of the RAW data, the transmission unit 411 of the terminal device 40 transmits the RAW data of the channel status information CSI of the downlink DL having the M-bit data amount previously calculated at T209 to the base station 20 (T215).

When the RAW data of the channel status information CSI is received by the reception unit 212 of the base station 20, the control unit 24 of the base station 20 compares the RAW data with the data previously decoded at T212, and determines whether or not the both completely match or whether or not the both match within an allowable error range, thereby verifying whether or not the data previously received from the terminal device 40 at T211 is correctly encoded (T216).

As described above, in the wireless communication system 1 according to the second embodiment of the present disclosure, the terminal device 40 normally transmits encoded data to the base station 20, and in a case where a semi-persistent transmission execution notification of the RAW data is received from the base station 20, transmits the RAW data to the base station 20 in a semi-persistent manner.

Note that, similarly to the first modification of the first embodiment described above, the terminal device 40 may normally transmit RAW data to the base station 20, and may transmit encoded data to the base station 20 in a semi-persistent manner in a case where a semi-persistent transmission execution notification of the encoded data is received from the base station 20.

Alternatively, similarly to the second modification of the first embodiment described above, in conjunction with the semi-persistent transmission of the channel status information CSI from the terminal device 40 to the base station 20, a semi-persistent transmission execution notification of the RAW data or the encoded data may be included in the signal transmitted and received at this time. For example, one of the configurations of the semi-persistent channel status information CSI transmitted from the base station to the terminal device 40 may include a configuration of semi-persistent transmission of RAW data or encoded data.

In addition, whether to transmit RAW data or encoded data may be determined on the terminal device 40 side. Alternatively, similarly to the third modification of the first embodiment described above, the terminal device 40 may always transmit RAW data or encoded data, for example, in a specific time slot.

### Third Embodiment

Next, a third embodiment of the present disclosure will be described. The third embodiment is performed in a case where data received from the terminal device 40 is not correctly encoded in the first embodiment or the second embodiment described above.

Specifically, in the third embodiment, after the “training execution notification” is transmitted from the base station 20 to the terminal device 40 and the encoder 43 is re-trained, the “training execution completion notification” or the “training execution failure notification” is transmitted from the terminal device 40 to the base station 20.

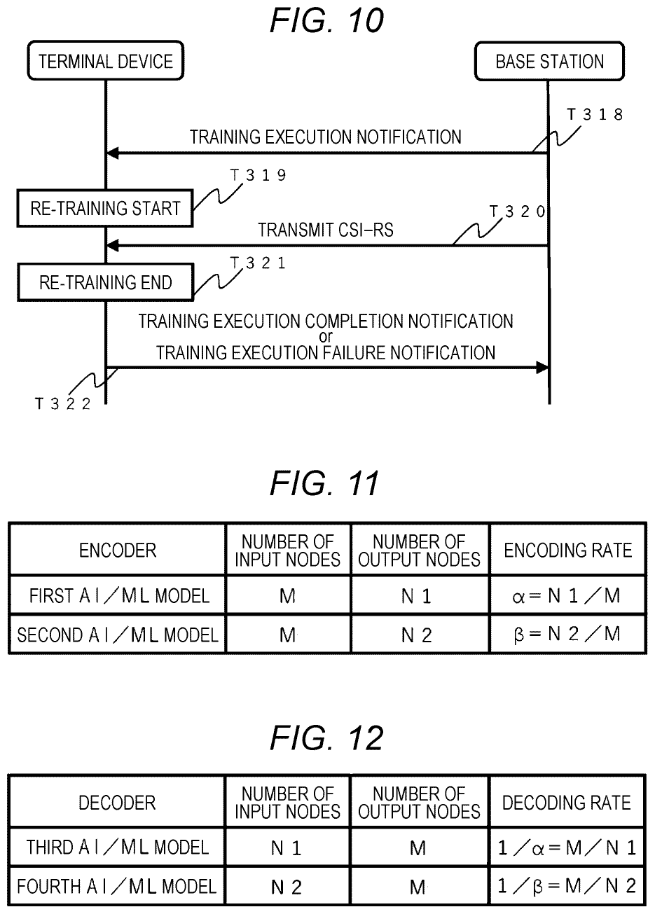

Hereinafter, details of processing in the wireless communication system 1 according to the third embodiment will be described with reference to a sequence diagram of FIG. 10. The processing of the sequence diagram of FIG. 10 is performed in a case where it is determined that the data received from the terminal device 40 is not correctly encoded at T117 of FIG. 8 according to the first embodiment or T216 of FIG. 9 according to the second embodiment described above.

The transmission unit 211 of the base station 20 transmits the training execution notification to the terminal device 40 (T318). The training execution notification includes a training data set for re-training the AI/ML model constituting the encoder 43, and parameters such as a training time or the number of training times.

When the training execution notification is received by the reception unit 412 of the terminal device 40, the control unit 44 of the terminal device 40 starts the re-training of the AI/ML model constituting the encoder 43 (T319).

Note that, in the course of re-training the AI/ML model constituting the encoder 43, the reference signal CSI-RS for channel status estimation is transmitted from the base station 20 to the terminal device 40 (T320), but the terminal device 40 may not estimate the channel status during the training. Alternatively, the terminal device 40 may use the reception information for training.

When the re-training of the AI/ML model constituting the encoder 43 is completed (T321), the control unit 44 of the terminal device 40 determines whether or not the training is successful, and the transmission unit 411 of the terminal device 40 transmits a training execution completion notification or a training execution failure notification to the base station 20 (T322).

Such a training execution completion notification or a training execution failure notification can be transmitted by being included in data or the like flowing through, for example, uplink control information (PCI), MAC-CE, or a physical uplink shared channel (PUSCH). Alternatively, instead of transmitting the training execution completion notification from the terminal device 40 to the base station 20, the base station 20 may determine that the training is completed in a case where the training execution failure notification from the terminal device 40 is not received within a predetermined time.

As described above, in the wireless communication system 1 according to the third embodiment of the present disclosure, the base station 20 transmits a training execution notification of the encoder 43 to the terminal device 40. Upon receiving the training execution notification of the encoder 43, the terminal device 40 starts training of the AI/ML model constituting the encoder 43, transmits a training execution completion notification to the base station 20 in a case where the training is successful, and transmits a training execution failure notification to the base station 20 in a case where the training is failed.

Note that, as a specific aspect that requires re-training of the AI/ML model constituting the encoder 43, in addition to the case where the original training of the encoder 43 is insufficient as described above, for example, there may be a case where the state of the transmission path between the terminal device 40 and the base station 20 has changed, a case where the AI/ML model constituting the decoder 23 has changed, or the like.

### Fourth Embodiment

Next, a fourth embodiment of the present disclosure will be described. In the fourth embodiment, the encoding rate of the encoder 43 is changed in stages in the course of training the AI/ML model constituting the encoder 43 of the terminal device 40.

Specifically, as illustrated in FIG. 11, the encoder 43 of the terminal device 40 is configured to be able to switch between the first AI/ML model with the encoding rate α=N1/M and the second AI/ML model with the encoding rate β=N2/M. Here, N1, N2, and M are positive numbers, and M>N1>N2. Therefore, α and β are also positive numbers, and α>β.

The first AI/ML model is a neural network model, its input layer 43a includes M nodes 43d, and its output layer 43c includes N1 nodes 43d. The second AI/ML model is also a neural network model, and its input layer 43a includes M nodes 43d, and its output layer 43c includes N2 nodes 43d.

Furthermore, as illustrated in FIG. 12, the decoder 23 of the base station 20 is configured to be able to switch between the third AI/ML model with the decoding rate 1/α=M/N1 and the fourth AI/ML model with the decoding rate 1/β=M/N2.

The third AI/ML model is a neural network model, its input layer 23a includes N1 nodes 23d, and its output layer 23c includes M nodes 23d. The fourth AI/ML model is also a neural network model, its input layer 23a includes N2 nodes 23d, and its output layer 23c includes M nodes 23d.

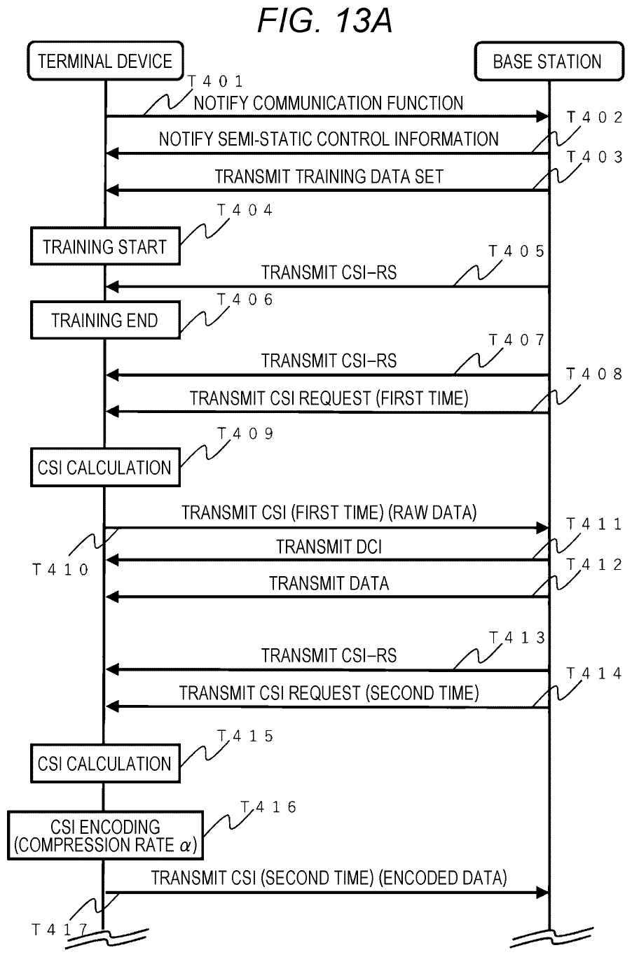

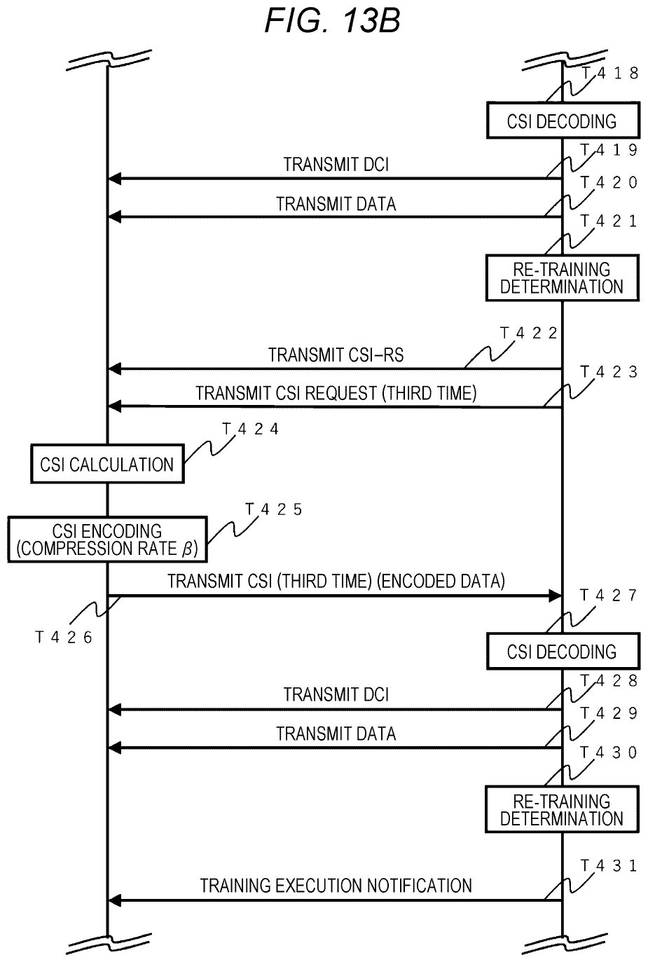

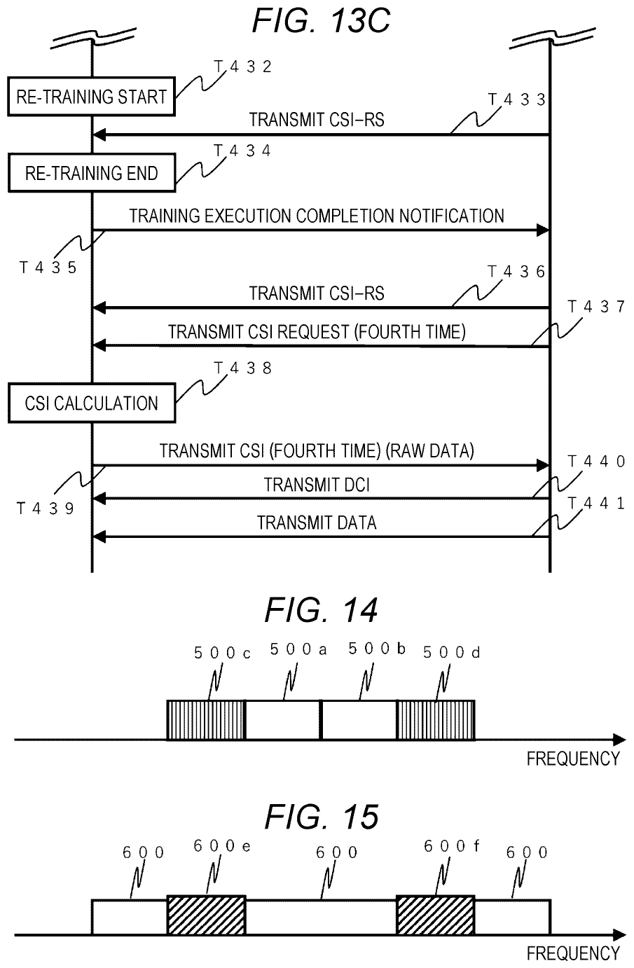

Hereinafter, details of processing in the wireless communication system 1 according to the fourth embodiment will be described with reference to sequence diagrams of FIGS. 13A to 13C. However, in the sequence diagrams of FIGS. 13A to 13C, the third and fourth AI/ML models constituting the decoder 23 of the base station 20 will be described on the assumption that sufficient training is performed in advance.

First, the transmission unit 411 of the terminal device 40 notifies the base station 20 of its own communication function (T401). The communication function includes a function related to the technology according to the fourth embodiment. Specifically, this is a function of changing the encoding rate of the encoder 43 in stages in the course of training of the encoder 43.

The transmission unit 211 of the base station 20 notifies the terminal device 40 of semi-static control information related to the technology according to the present fourth embodiment (T402). The semi-static control information includes information instructing, when the channel status information CSI is transmitted from the terminal device 40 to the base station 20, first transmission of RAW data, second transmission of data encoded at the encoding rate α, and third transmission of data encoded at the encoding rate β.

Next, the transmission unit 211 of the base station 20 transmits a training data set for training the first and second AI/ML models constituting the encoder 43 of the terminal device 40 to the terminal device 40 (T403).

When the above-described training data set is received by the reception unit 412 of the terminal device 40, the control unit 44 of the terminal device 40 starts training of the first and second AI/ML models constituting the encoder 43 using the received training data set (T404).

When the training of the first and second AI/ML models constituting the encoder 43 is completed (T406), the channel status information CSI can be transmitted as encoded data from the terminal device 40 to the base station 20.

Next, the transmission unit 211 of the base station 20 transmits a reference signal CSI-RS for channel status estimation to the terminal device 40 (T407), and then transmits a first transmission request for channel status information CSI to the terminal device 40 (T408).

When this first transmission request is received by the reception unit 412 of the terminal device 40, the control unit 44 of the terminal device 40 calculates M-bit channel status information CSI on the basis of the reference signal CSI-RS for channel status estimation previously received at T407 (T409). The transmission unit 411 of the terminal device 40 transmits the RAW data of this channel status information CSI to the base station 20 (T410). Note that the RAW data of the channel status information CSI can also be interpreted as data encoded at an encoding rate of M/M=1.

When the RAW data of the channel status information CSI is received by the reception unit 212 of the base station 20, the control unit 24 of the base station 20 schedules transmission from the base station 20 to the terminal device 40 via the downlink DL on the basis of the reception. The transmission unit 211 of the base station transmits downlink control information DCI including a result of the scheduling to the terminal device 40 (T411), and then, performs data transmission to the terminal device 40 via the PDSCH (T412).

Next, the transmission unit 411 of the base station 20 transmits a reference signal CSI-RS for channel status estimation to the terminal device 40 (T413), and then transmits a second transmission request for channel status information CSI to the terminal device 40 (T414).

When this second transmission request is received by the reception unit 412 of the terminal device 40, the control unit 44 of the terminal device 40 calculates M-bit channel status information CSI on the basis of the reference signal CSI-RS for channel status estimation previously received at T413 (T415).

The control unit 44 of the terminal device 40 sets the encoding rate of the encoder 43 to a. Specifically, the configuration of the encoder 43 is switched to the first AI/ML model of the encoding rate α=N1/M. Then, when the RAW data of the M-bit channel status information CSI calculated at T415 is input to the encoder 43, N1-bit encoded data is output from the encoder 43 (T416). The transmission unit 411 of the terminal device 40 transmits the N1-bit encoded data to the base station 20 (T417).

When the N1-bit encoded data is received by the reception unit 212 of the base station 20 and input to the decoder 23, the M-bit channel status information CSI is restored and output from the decoder 23 (T418). At this time, the configuration of the decoder 23 is switched to the third AI/ML model with the decoding rate 1/α=M/N1.

The control unit 24 of the base station 20 performs scheduling of transmission via the downlink DL from the base station 20 to the terminal device 40 on the basis of the restored channel status information CSI. The transmission unit 211 of the base station transmits downlink control information DCI including a result of the scheduling to the terminal device 40 (T419), and then, performs data transmission to the terminal device 40 via the PDSCH (T420).

The control unit 24 of the base station 20 determines whether or not the first AI/ML model constituting the encoder 43 of the terminal device 40 needs to be re-trained on the basis of the comparison between the RAW data previously received at T410 and the data decoded at T418 (T421). Specifically, the control unit 24 of the base station 20 determines that the re-training does not need to be performed in a case where the both completely match each other or the both match each other within an allowable error range. On the other hand, in a case where the both do not completely coincide with each other and do not coincide with each other even within an allowable error range, the control unit 24 of the base station 20 determines that the re-training needs to be performed. Here, the following description will be continued on the assumption that it is determined at T421 that re-training is not necessary.

Next, the transmission unit 211 of the base station 20 transmits a reference signal CSI-RS for channel status estimation to the terminal device 40 (T422), and then transmits a third transmission request for channel status information CSI to the terminal device 40 (T423).

When this third transmission request is received by the reception unit 412 of the terminal device 40, the control unit 44 of the terminal device 40 calculates M-bit channel status information CSI on the basis of the reference signal CSI-RS for channel status estimation previously received at T422 (T424).

The control unit 44 of the terminal device 40 sets the encoding rate of the encoder 43 to B. Specifically, the configuration of the encoder 43 is switched to the second AI/ML model with the encoding rate β=N2/M. Then, when the RAW data of the M-bit channel status information CSI calculated at T424 is input to the encoder 43, N2-bit encoded data is output from the encoder 43 (T425). The transmission unit 411 of the terminal device 40 transmits the N2-bit encoded data to the base station 20 (T426).

When the N2-bit encoded data is received by the reception unit 412 of the base station 20 and input to the decoder 23, the M-bit channel status information CSI is restored and output from the decoder 23 (T427). At this time, the configuration of the decoder 23 is switched to the fourth AI/ML model with the decoding rate 1/β=M/N2.

The control unit 24 of the base station 20 performs scheduling of transmission via the downlink DL from the base station 20 to the terminal device 40 on the basis of the restored channel status information CSI. The transmission unit 211 of the base station transmits downlink control information DCI including a result of the scheduling to the terminal device 40 (T428), and then, performs data transmission to the terminal device 40 via the PDSCH (T429).

The control unit 24 of the base station 20 determines whether or not the second AI/ML model constituting the encoder 43 of the terminal device 40 needs to be re-trained on the basis of the comparison between the RAW data previously received at T410 and the data decoded at T427 (T430). Specifically, the control unit 24 of the base station 20 determines that the re-training does not need to be performed in a case where the both completely match each other or the both match each other within an allowable error range. On the other hand, in a case where the both do not completely coincide with each other and do not coincide with each other even within an allowable error range, the control unit 24 of the base station 20 determines that the re-training needs to be performed. Here, the following description will be continued assuming that it is determined at T430 that re-training is necessary.

The transmission unit 211 of the base station 20 transmits the training execution notification to the terminal device 40 (T431). The training execution notification includes a training data set for re-training of the second AI/ML model of the encoding rate β constituting the encoder 43.

When the training execution notification is received by the reception unit 412 of the terminal device 40, the control unit 44 of the terminal device 40 starts the re-training of the second AI/ML model constituting the encoder 43 (T432).

When the re-training of the second AI/ML model constituting the encoder 43 ends (T434), the control unit 44 of the terminal device 40 determines whether or not the training has succeeded. Here, the transmission unit 411 of the terminal device 40 transmits a training execution completion notification to the base station 20 on the assumption that the training has succeeded (T435).

Subsequent processing from T436 is similar to the processing from T407 described above. However, the fifth training determination is performed for the second AI/ML model of the encoding rate β.

As described above, in the wireless communication system 1 according to the fourth embodiment of the present disclosure, the encoding rate of the encoder 43 is changed in stages in the course of training the AI/ML model constituting the encoder 43 of the terminal device 40. Such a training method can be interpreted as multi-step training. On the other hand, the third embodiment described above can be interpreted as single-step training.

In the single-step training, the encoding rate of the encoder 43 and the decoding rate of the decoder 23 are fixed to a single value determined in advance. On the other hand, in the multi-step training, the encoding rate of the encoder 43 and the decoding rate of the decoder 23 are selected in stages from a plurality of candidates determined in advance.

With the above features, for example, the lowest encoding rate at which the decoder 23 can correctly decode can be determined by proceeding with training while decreasing the encoding rate of the encoder 43 in stages. More specifically, for example, it can be considered that the encoding rate immediately before the encoding rate at which the decoder 23 fails to correctly decode is the lowest encoding rate at which the decoder 23 can correctly decode. Then, once the encoding rate is determined, the encoding rate is fixed to the encoding rate.

Note that the plurality of candidates for the encoding rate and the decoding rate may be determined in advance as specifications, or may be determined by the base station 20 at the start of training and the notification is provided to the terminal device 40. Furthermore, the base station 20 may determine from which encoding rate the training is started and notify the terminal device 40 of the determined encoding rate. For example, the encoding rate at the start of training may be started from a value slightly smaller than 1 instead of M/M=1.

Furthermore, in the plurality of candidates of the encoding rate of the encoder 43 illustrated in FIG. 11, the number of input nodes, that is, the bit depth of the RAW data is constant, and the number of output nodes, that is, the bit depth of the encoded data changes. Alternatively, the bit depth of the encoded data may be made constant, and the bit depth of the RAW data may be changed. Alternatively, both the bit depth of RAW data and the bit depth of encoded data may be changed.

Furthermore, similarly, in the plurality of candidates of the decoding rate of the decoder 23 illustrated in FIG. 12, the number of output nodes, that is, the bit depth of the decoded data is constant, and the number of input nodes, that is, the bit depth of the encoded data changes. Alternatively, the bit depth of the encoded data may be made constant, and the bit depth of the decoded data may be changed. Alternatively, both the bit depth of encoded data and the bit depth of decoded data may be changed.

### VARIOUS MODIFICATIONS

Note that, in each of the above embodiments, in a case where a plurality of pieces of channel status information CSI corresponding to a plurality of frequency subbands is transmitted when the channel status information CSI is transmitted from the terminal device 40 to the base station 20, whether to transmit encoded data or RAW data may be determined according to the characteristics of each subband.

For example, in FIG. 14, in the subbands 500a and 500b in which the data amount of the channel status information CSI is large, the channel status information CSI is transmitted as normally encoded data, and RAW data for verification is transmitted aperiodically or in a semi-persistent manner, thereby reducing the amount of data to be transmitted. On the other hand, in the subbands 500c and 500d in which the data amount of the channel status information CSI is small, the channel status information CSI is always transmitted as the RAW data, and thus, the accuracy of the data is prioritized over the reduction in the amount of data to be transmitted.

In addition, in FIG. 15, the channel status information CSI is transmitted as encoded data in the entire frequency band 600. Then, when the RAW data is transmitted in order to verify whether or not the RAW data is correctly encoded, a part of the RAW data is transmitted only in specific subbands 600e and 600f. In a case where the entire RAW data can be estimated from a part of the RAW data on the base station 20 side for reasons such as regularity in the RAW data, the amount of data transmitted for verification is suppressed by transmitting a part of the RAW data in this manner. Note that a part of the RAW data may be transmitted in the entire frequency band 600, and the encoded data may be transmitted in specific subbands 600e and 600f.

Furthermore, the AI/ML model constituting the encoder 43 of the terminal device 40 may be unique to each terminal device 40 or may be unique to each cell. For example, in a case where each terminal device 40 uses an AI/ML model unique to its own device, the base station 20 has a plurality of AI/ML models corresponding to the AI/ML models of each terminal device 40. Furthermore, in a case where the terminal device 40 uses the AI/ML model unique to each cell, the base station 20 also uses the AI/ML model unique to each cell.

Furthermore, the update of the AI/ML model constituting the encoder 43 of the terminal device 40 may be performed for each cell or for each frequency band. At this time, the base station 20 may notify each terminal device 40 of the update of the AI/ML model by system information or the like. Each terminal device 40 that has received this notification temporarily suspends the use of the encoder 43 and starts updating the AI/ML model.

Furthermore, the terminal device 40 may temporarily suspend the use of the encoder 43 during training or re-training of the AI/ML model constituting the encoder 43. In this case, all the data transmitted from the terminal device 40 to the base station 20 during this time is transmitted as RAW data.

In addition, in training of the AI/ML model constituting the encoder 43 of the terminal device 40, accuracy and a method may be changed on the basis of information such as 5G Qos Identifier (5QI), Qos, a communication function of the terminal device 40, RRC configuration, and system information. For example, in a case where the request for the spectrum use efficiency is high, the accuracy of the training may be increased. Furthermore, a training method may be selected according to the use case, such as performing multi-step training in the case of a use case such as streaming, and performing single-step training in the case of a use case such as one-shot data transmission.

Furthermore, instead of training the AI/ML model constituting the encoder 43 on the terminal device 40 side, the model parameters may be transferred to the terminal device 40 after training on the base station 20 side. For example, in a case where the AI/ML model is a neural network model, the number of layers, the number of nodes included in each layer, the activation function of each node, the topology of edges connecting each node, the weight of each edge, and the like are transferred as model parameters. Alternatively, a plurality of AI/ML models may be defined as specifications in advance, IDs may be assigned, and only the IDs may be transferred.

Furthermore, in order to verify the AI/ML model constituting the encoder 43 of the terminal device 40, the model parameter of the AI/ML model constituting the decoder 23 of the base station 20 may be transferred to the terminal device 40. Furthermore, the terminal device 40 may perform training of the AI/ML model constituting the encoder 43 using the model parameters of the AI/ML constituting the decoder 23 transferred from the base station 20. Regarding the transfer of the model parameters, for example, model parameters unique to each terminal device 40 may be transferred by RRC signaling or the like, or model parameters common to all the terminal devices 40 may be transferred by a system information block (SIB) or the like. Furthermore, the model parameters of the trained AI/ML model constituting the encoder 43 of the terminal device 40 may be transferred to the base station 20.

Furthermore, training of the AI/ML model constituting the encoder 43 of the terminal device 40 may be performed at the time of RRC idle. Furthermore, the training data set is not created on the base station 20 side and provided to the terminal device 40, but each of the terminal device 40 and the base station 20 may independently create the training data set.

Furthermore, the data to which the technology according to the present disclosure can be applied is not limited to the channel status information CSI transmitted from the terminal device 40 to the base station 20. That is, the technology according to the present disclosure can be similarly applied to other types of data transmitted from the terminal device 40 to the base station 20. Furthermore, the technology according to the present disclosure can be similarly applied to arbitrary data transmitted from the base station 20 to the terminal device 40. In that case, the base station 20 serves as a transmission side including an encoder, and the terminal device 40 serves as a reception side including a decoder. More generally, the technology according to the present disclosure can be similarly applied to arbitrary data transmitted and received between two or more communication devices.

Furthermore, the technology according to the present disclosure can also be applied when reducing the signal processing amounts on the transmission side and the reception side using the AI/ML model. Furthermore, the technology according to the present disclosure can also be applied when signal processing suitable for a channel status is performed on the transmission side and the reception side using the AI/ML model. More generally, the technology according to the present disclosure can be similarly applied when arbitrary signal processing is performed on the transmission side and/or the reception side using the AI/ML model.

Note that the processing in the present disclosure is not limited to a specific standard, and the exemplified setting may be appropriately changed. Note that the respective embodiments described above illustrate examples for embodying the present disclosure, and the present disclosure can be implemented in various other modes. For example, various modifications, substitutions, omissions, or combinations thereof can be made without departing from the gist of the present disclosure. Such modifications, substitutions, omissions, and the like are also included in the scope of the present disclosure, and are similarly included in the inventions disclosed in the claims and the equivalents thereof.

Furthermore, the procedures of processing described in the present disclosure may be regarded as a method having a series of these procedures. Alternatively, the procedures may be regarded as a program for causing a computer to execute the series of these procedures or a recording medium storing the program. In addition, the processing described above is executed by a processor such as a CPU of a computer. Furthermore, the type of the recording medium does not affect the embodiments of the present disclosure, and thus is not particularly limited.

Note that each component illustrated in FIGS. 2 to 6 in the present disclosure may be realized by software or hardware. For example, each component may be a software module realized by software such as a microprogram, and each component may be realized by the processor executing the software module. Alternatively, each component may be realized by a circuit block on a semiconductor chip (die), for example, an integrated circuit such as an application specific integrated circuit (ASIC) or a field programmable gate array (FPGA). In addition, the number of components and the number of pieces of hardware for realizing the components may not coincide with each other. For example, one processor or circuit may realize a plurality of components. Conversely, one component may be realized by a plurality of processors or circuits.

Note that the type of the processor described in the present disclosure is not limited. For example, a CPU, a micro processing unit (MPU), a graphics processing unit (GPU), or the like may be used.

Furthermore, although the utilization of the present disclosure in the neural network model has been described above, the present disclosure is not necessarily limited thereto. For example, a similar configuration may be used in a spiking neural network model or the like. In addition, it may be used to solve a problem different from utilization in the neural network model at that time. A spike signal may be used to transmit any type of the information described above. Furthermore, the causal relationship may be extracted from the time-series data, and any of the determinations described above may be performed on the basis of the information.

Note that the present disclosure can also have the following configurations.
[1]
A transmission device including: an encoder configured by an AI/ML model, and configured to encode a first bit sequence or symbol sequence to acquire a second bit sequence or symbol sequence; and
a transmission unit that transmits the first bit sequence or symbol sequence and the second bit sequence or symbol sequence.
[2]
The transmission device according to [1], in which the transmission unit transmits the first bit sequence or symbol sequence aperiodically or in a semi-persistent manner.
[3]
The transmission device according to [2], in which the transmission unit transmits the first bit sequence or symbol sequence aperiodically according to an aperiodic transmission execution notification of the first bit sequence or symbol sequence.
[4]
The transmission device according to [2], in which the transmission unit transmits the first bit sequence or symbol sequence in a semi-persistent manner according to a semi-persistent transmission execution notification of the first bit sequence or symbol sequence.
[5]
The transmission device according to any one of [1] to [4], further including a control unit that starts training of the AI/ML model constituting the encoder according to a training execution notification of the encoder.
[6]
The transmission device according to [5], in which the transmission unit is configured to:

transmit a training execution completion notification of the encoder in a case where training of the AI/ML model constituting the encoder has succeeded; and
transmit a training execution failure notification of the encoder in a case where training of the AI/ML model constituting the encoder has failed.
[7]
The transmission device according to any one of [1] to [6], further including a control unit that performs training of the AI/ML model constituting the encoder, in which the control unit changes an encoding rate of the encoder in a course of the training.
[8]
A reception device including: a reception unit that receives a first bit sequence or symbol sequence and a second bit sequence or symbol sequence acquired by encoding the first bit sequence or symbol sequence;
a decoder configured by an AI/ML model, and configured to decode the second bit sequence or symbol sequence to acquire a decoded bit sequence or symbol sequence; and
a control unit that verifies the second bit sequence or symbol sequence on the basis of a comparison between the first bit sequence or symbol sequence and the decoded bit sequence or symbol sequence.
[9]
The reception device according to [8], in which the reception unit receives the first bit sequence or symbol sequence aperiodically or in a semi-persistent manner.
[10]
The reception device according to [9], further including a transmission unit that transmits an aperiodic transmission execution notification of the first bit sequence or symbol sequence,
in which the reception unit receives the first bit sequence or symbol sequence aperiodically.
[11]
The reception device according to [9], further including a transmission unit that transmits a semi-persistent transmission execution notification of the first bit sequence or symbol sequence,
in which the reception unit receives the first bit sequence or symbol sequence in a semi-persistent manner.
[12]
The reception device according to any one of [8] to [11], further including a transmission unit that transmits a training execution notification of an encoder corresponding to the decoder.
[13]
The reception device according to [12], in which the reception unit receives a training execution completion notification or a training execution failure notification of the encoder.
[14]
The reception device according to any one of [8] to [13], further including a control unit that changes a decoding rate of the decoder in a course of training an AI/ML model constituting an encoder corresponding to the decoder.
[15]
A transmission method including the steps of:
encoding a first bit sequence or symbol sequence by an encoder configured by an AI/ML model, to acquire a second bit sequence or symbol sequence; and
transmitting the second bit sequence or symbol sequence and the first bit sequence or symbol sequence.
[16]
A reception method including the steps of:
receiving a first bit sequence or symbol sequence and a second bit sequence or symbol sequence acquired by encoding the first bit sequence or symbol sequence;
decoding the second bit sequence or symbol sequence by a decoder configured by an AI/ML model, to acquire a decoded bit sequence or symbol sequence; and
verifying the first bit sequence or symbol sequence on the basis of a comparison of the first bit sequence or symbol sequence and the decoded bit sequence or symbol sequence.

### REFERENCE SIGNS LIST

1 Wireless communication system
40 Terminal device (transmission device)
411 Transmission unit
412 Reception unit
43 Encoder
43a Input layer
43b Hidden layer
43c Output layer
43d Node
43e Edge
44 Control unit
20 Base station
211 Transmission unit
212 Reception unit
23 Decoder
23a Input layer
23b Hidden layer
23c Output layer
23d Node
23e Edge
24 Control unit
RAN Radio access network
CN Core network
500a Subband
500b Subband
500c Subband
500d Subband
600 Wideband
600e Subband
600f Subband

1. A transmission device comprising: an encoder configured by an AI/ML model, and configured to encode a first bit sequence or symbol sequence to acquire a second bit sequence or symbol sequence; and
a transmission unit that transmits the first bit sequence or symbol sequence and the second bit sequence or symbol sequence.

2. The transmission device according to claim 1, wherein the transmission unit transmits the first bit sequence or symbol sequence aperiodically or in a semi-persistent manner.

3. The transmission device according to claim 2, wherein the transmission unit transmits the first bit sequence or symbol sequence aperiodically according to an aperiodic transmission execution notification of the first bit sequence or symbol sequence.

4. The transmission device according to claim 2, wherein the transmission unit transmits the first bit sequence or symbol sequence in a semi-persistent manner according to a semi-persistent transmission execution notification of the first bit sequence or symbol sequence.

5. The transmission device according to claim 1, further comprising a control unit that starts training of the AI/ML model constituting the encoder according to a training execution notification of the encoder.

6. The transmission device according to claim 5, wherein the transmission unit is configured to:
transmit a training execution completion notification of the encoder in a case where training of the AI/ML model constituting the encoder has succeeded; and
transmit a training execution failure notification of the encoder in a case where training of the AI/ML model constituting the encoder has failed.

7. The transmission device according to claim 1, further comprising a control unit that performs training of the AI/ML model constituting the encoder, wherein the control unit changes an encoding rate of the encoder in a course of the training.

8. A reception device comprising: a reception unit that receives a first bit sequence or symbol sequence and a second bit sequence or symbol sequence acquired by encoding the first bit sequence or symbol sequence;
a decoder configured by an AI/ML model, and configured to decode the second bit sequence or symbol sequence to acquire a decoded bit sequence or symbol sequence; and
a control unit that verifies the second bit sequence or symbol sequence on a basis of a comparison between the first bit sequence or symbol sequence and the decoded bit sequence or symbol sequence.

9. The reception device according to claim 8, wherein the reception unit receives the first bit sequence or symbol sequence aperiodically or in a semi-persistent manner.

10. The reception device according to claim 9, further comprising a transmission unit that transmits an aperiodic transmission execution notification of the first bit sequence or symbol sequence,
wherein the reception unit receives the first bit sequence or symbol sequence aperiodically.

11. The reception device according to claim 9, further comprising a transmission unit that transmits a semi-persistent transmission execution notification of the first bit sequence or symbol sequence,
wherein the reception unit receives the first bit sequence or symbol sequence in a semi-persistent manner.

12. The reception device according to claim 8, further comprising a transmission unit that transmits a training execution notification of an encoder corresponding to the decoder.

13. The reception device according to claim 12, wherein the reception unit receives a training execution completion notification or a training execution failure notification of the encoder.

14. The reception device according to claim 8, further comprising a control unit that changes a decoding rate of the decoder in a course of training an AI/ML model constituting an encoder corresponding to the decoder.

15. A transmission method comprising the steps of:
encoding a first bit sequence or symbol sequence by an encoder configured by an AI/ML model, to acquire a second bit sequence or symbol sequence; and
transmitting the second bit sequence or symbol sequence and the first bit sequence or symbol sequence.

16. A reception method comprising the steps of:
receiving a first bit sequence or symbol sequence and a second bit sequence or symbol sequence acquired by encoding the first bit sequence or symbol sequence;
decoding the second bit sequence or symbol sequence by a decoder configured by an AI/ML model, to acquire a decoded bit sequence or symbol sequence; and
verifying the second bit sequence or symbol sequence on a basis of a comparison of the first bit sequence or symbol sequence and the decoded bit sequence or symbol sequence.
